(19) United States
(12) Patent Application Publication
(10) Pub. No.: US 2026/0173412 A1
(43) Pub. Date: Jun. 18, 2026

(54) SEMICONDUCTOR PACKAGE

(71) Applicant: Samsung Electronics Co., Ltd., Suwon-si (KR)

(72) Inventors: Jaewon KIM, Suwon-si (KR); Seunghyeon PARK, Suwon-si (KR)

(73) Assignee: Samsung Electronics Co., Ltd., Suwon-si (KR)

(21) Appl. No.: 19/407,618

(22) Filed: Dec. 3, 2025

(30) Foreign Application Priority Data
Dec. 12, 2024 (KR) 10-2024-0184563

(51) Int. Cl. H10D 1/68

(52) U.S. Cl. CPC H10D 1/692; H10W 70/65; H10W 90/00

(57) ABSTRACT

A semiconductor package includes a substrate structure having a first mounting region and a second mounting region, at least one semiconductor chip stacked on the first mounting region of the substrate structure, and a double electrode capacitor stacked on the second mounting region of the substrate structure. The double electrode capacitor includes a pair of first external electrodes electrically connected to the substrate structure, a body portion including a plurality of insulating layers between the pair of first external electrodes and a plurality of internal electrodes between the plurality of insulating layers and extending in a horizontal direction so as to at least partially contact a portion of the pair of first external electrodes, and a lower bump structure protruding vertically downward from a lowermost insulating layer among the plurality of insulating layers of the body portion. The lower bump structure is in contact with the substrate structure.

### CROSS-REFERENCE TO RELATED APPLICATIONS

This application claims priority under 35 U.S.C. § 119 to Korean Patent Application No. 10-2024-0184563, filed on Dec. 12, 2024 in the Korean Intellectual Property Office (KIPO), the contents of which are herein incorporated by reference in their entirety.

### BACKGROUND

### 1. Field

Example embodiments relate to semiconductor packages and methods of manufacturing the semiconductor package. More particularly, example embodiments relate to semiconductor packages having a multi-layer ceramic capacitor (MLCC).

### 2. Description of the Related Art

In order to stably supply power at a constant level, semiconductor packages utilizing multi-layer ceramic capacitors (MLCCs) are increasing. The capacitor may include at least one pair of electrodes and a ceramic body provided between the one pair of electrodes. For example, the capacitor may be mounted on a substrate structure using an adsorption nozzle that picks up the capacitor in a vacuum adsorption manner. At this time, only the electrodes of the capacitor may be supported by conductive connecting members such as solder paste, and a gap may be formed between the substrate structure and a lower portion of the ceramic body. During the mounting process, because only the electrodes of the capacitor are supported by the conductive connecting members, a repulsive force may be generated only in the conductive connecting members, and accordingly, a bending force may be applied to the capacitor by an external force applied by the adsorption nozzle. Thus, cracks may occur in the capacitor due to the bending force, which may reduce the quality and/or yield of the semiconductor package.

### SUMMARY

Some example embodiments provide semiconductor packages including a capacitor having a structure for reducing or preventing cracks.

Some example embodiments provide methods of manufacturing the semiconductor package.

According to an example embodiment, a semiconductor package includes a substrate structure having a first mounting region and a second mounting region, at least one semiconductor chip on the first mounting region of the substrate structure, and a double electrode capacitor on the second mounting region of the substrate structure. The double electrode capacitor includes a pair of first external electrodes electrically connected to the substrate structure, a body portion including a plurality of insulating layers between the pair of first external electrodes, and a plurality of internal electrodes between the plurality of insulating layers and extending in a horizontal direction so as to at least partially contact a portion of the pair of first external electrodes, and a lower bump structure protruding vertically downward from a lowermost insulating layer among the plurality of insulating layers of the body portion. The lower bump structure is in contact with the substrate structure.

According to an example embodiment, a semiconductor package includes a substrate structure having a first mounting region and a second mounting region, at least one semiconductor chip on the first mounting region of the substrate structure, and a quadruple electrode capacitor on the second mounting region of the substrate structure and electrically connected to the substrate structure. The quadruple electrode capacitor includes a pair of first external electrodes spaced apart from each other in a horizontal direction, a pair of second external electrodes spaced apart from the pair of first external electrodes in the horizontal direction, a body portion including a plurality of insulating layers between the pair of first external electrodes and the pair of second external electrodes, and a plurality of internal electrodes between the plurality of insulating layers and extending in the horizontal direction so as to at least partially contact at least a portion of the pair of first external electrodes and the pair of second external electrodes, and a lower bump structure protruding downward in a vertical direction from a lowermost insulating layer among the plurality of insulating layers of the body portion. The lower bump structure is in contact with the substrate structure.

According to an example embodiment, a semiconductor package includes a first redistribution wiring layer having a first surface and a second surface opposite to the first surface, the first surface having a central region and a peripheral region surrounding the central region, at least one semiconductor chip on the central region of the first redistribution wiring layer, conductive pillars on the peripheral region of the first redistribution wiring layer, a molding member on the first surface of the first redistribution wiring layer, the molding member covering the at least one semiconductor chip and the conductive pillars and exposing a top surface of the conductive pillars, a second redistribution wiring layer on the molding member and electrically connected to the first redistribution wiring layer via the conductive pillars, and a double electrode capacitor on the second surface of the first redistribution wiring layer. The double electrode capacitor includes a pair of first external electrodes electrically connected to the first redistribution wiring layer, a body portion including a plurality of insulating layers and a plurality of internal electrodes, the plurality of insulating layers being between the pair of first external electrodes, the plurality of internal electrodes being between the plurality of insulating layers and extending in a horizontal direction so as to at least partially contact a portion of the pair of first external electrodes, a lower bump structure extending vertically from an uppermost insulating layer among the plurality of insulating layers of the body portion so as to come into contact with the first redistribution wiring layer.

According to an example embodiment, a semiconductor package may include a substrate structure, at least one semiconductor chip mounted on the substrate structure, and a double electrode capacitor mounted on the substrate structure.

The double electrode capacitor may include a pair of first external electrodes, a body portion including a plurality of insulating layers disposed between the pair of first external electrodes and a plurality of internal electrodes arranged between the plurality of insulating layers, and a lower bump structure protruding downward in a vertical direction from a lowermost insulating layer among the plurality of insulating layers. The lower bump structure may be in contact with the substrate structure.

Accordingly, the double electrode capacitor may be supported by the lower bump structure. Thus, the lower bump structure may reduce or prevent a bending force from being applied to the double electrode capacitor, and furthermore, the lower bump structure may reduce or prevent a crack from occurring in the double electrode capacitor.

According to an example embodiment, a method of manufacturing a semiconductor package may include providing a substrate structure having a first mounting region and a second mounting region, mounting at least one semiconductor chip on the first mounting region of the substrate structure, preparing a double electrode capacitor by providing a body portion including a plurality of insulating patterns and a plurality of internal electrodes therebetween, by forming a pair of first external electrodes at both ends of the body portion such that each of the pair of first external electrodes covers at least a side surface and a bottom surface of a corresponding one of both ends of the body portion and connected to one or more of the plurality of internal electrodes, and by forming a lower bump structure protruding vertically downward from a lowermost insulating layer among the plurality of insulating layers of the body portion, and mounting the double electrode capacitor on the second mounting region of the substrate structure so that a bottom surface of each of the pair of first external electrodes is connected to a substrate via a solder layer interposed therebetween and a bottom surface of lower bump structure contacts the substrate structure.

### BRIEF DESCRIPTION OF THE DRAWINGS

Example embodiments will be more clearly understood from the following detailed description taken in conjunction with the accompanying drawings. FIGS. 1 to 47 represent non-limiting, example embodiments as described herein.

FIG. 1 is a cross-sectional view illustrating a semiconductor package in accordance with an example embodiment.

FIG. 2 is an enlarged cross-sectional view illustrating portion ‘M1’ in FIG. 1.

FIG. 3 is a perspective view illustrating a capacitor in FIG. 1.

FIG. 4 is a cross-sectional view taken along the line C1-C1′ in FIG. 3.

FIGS. 5 to 24 are views illustrating a method of manufacturing a semiconductor package in accordance with an example embodiment.

FIG. 25 is a perspective view illustrating a capacitor in accordance with an example embodiment.

FIG. 26 is a cross-sectional view taken along the line C3-C3′ in FIG. 25.

FIG. 27 is a perspective view illustrating a capacitor in accordance with an example embodiment.

FIG. 28 is a cross-sectional view taken along the line C4-C4′ in FIG. 27.

FIG. 29 is a cross-sectional view taken along the line C5-C5′ in FIG. 27.

FIG. 30 is a perspective view illustrating a semiconductor package in accordance with an example embodiment.

FIG. 31 is a cross-sectional view taken along the line C6-C6′ in FIG. 30.

FIG. 32 is an enlarged cross-sectional view illustrating portion ‘M3’ in FIG. 31.

FIG. 33 is a perspective view illustrating the capacitor of FIG. 30.

FIG. 34 is a perspective view illustrating the capacitor of FIG. 30, wherein electrodes are omitted.

FIG. 35 is a plan view illustrating the capacitor of FIG. 30, wherein electrodes are omitted.

FIG. 36 is a perspective view illustrating internal electrodes of the capacitor of FIG. 30.

FIGS. 37 to 43 are views illustrating a method of manufacturing a capacitor in accordance with an example embodiment.

FIG. 44 is a perspective view illustrating a capacitor in accordance with an example embodiment.

FIG. 45 is a cross-sectional view taken along the line C8-C8′ in FIG. 43.

FIG. 46 is a cross-sectional view illustrating a semiconductor package in accordance with an example embodiment.

FIG. 47 is a cross-sectional view illustrating a semiconductor package in accordance with an example embodiment.

### DETAILED DESCRIPTION

Hereinafter, some example embodiments will be explained in detail with reference to the accompanying drawings.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers

### Present.

As used herein, expressions such as “one of,” “one or more of,” “any one of,” “at least one of,” and “at least one selected from” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

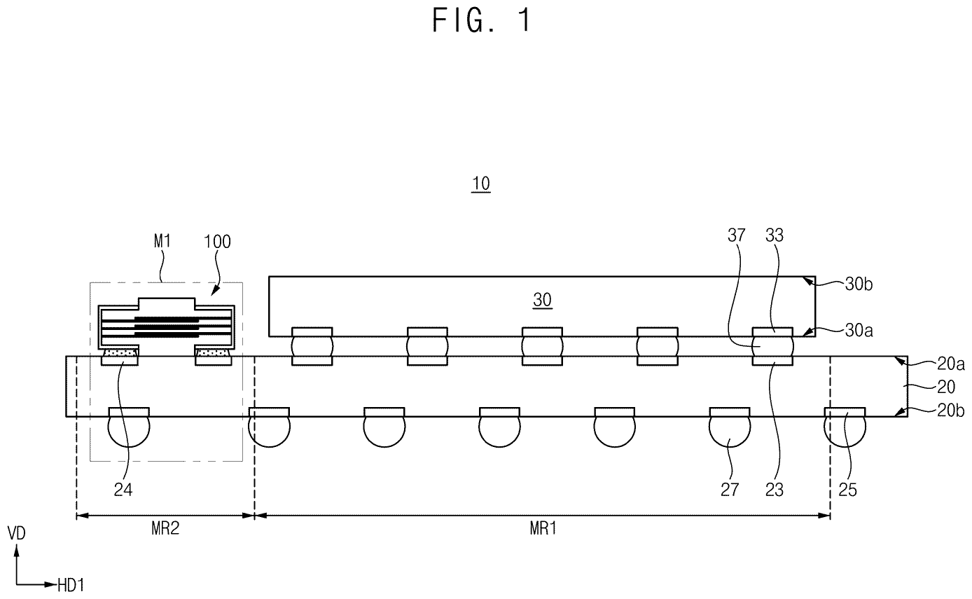

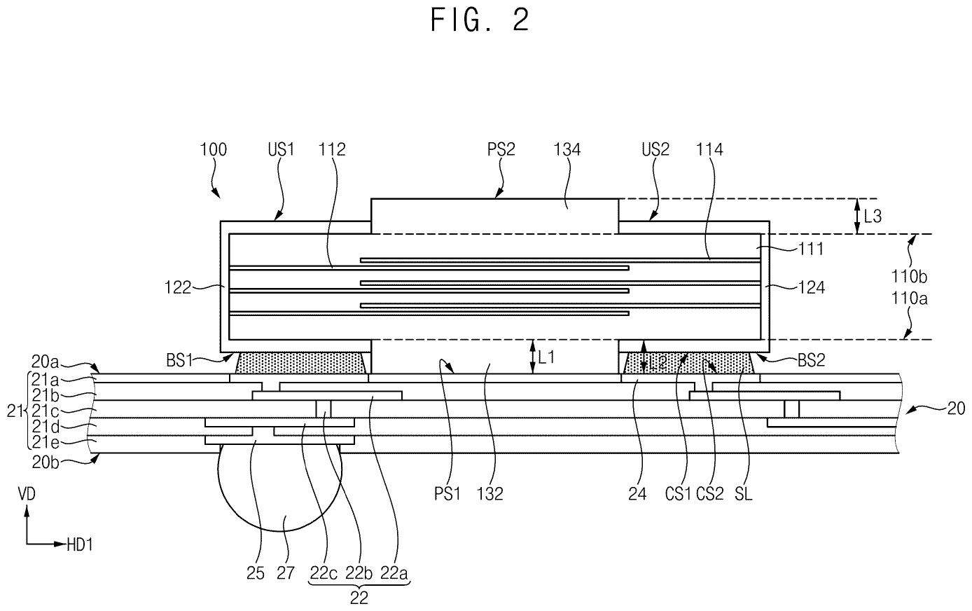

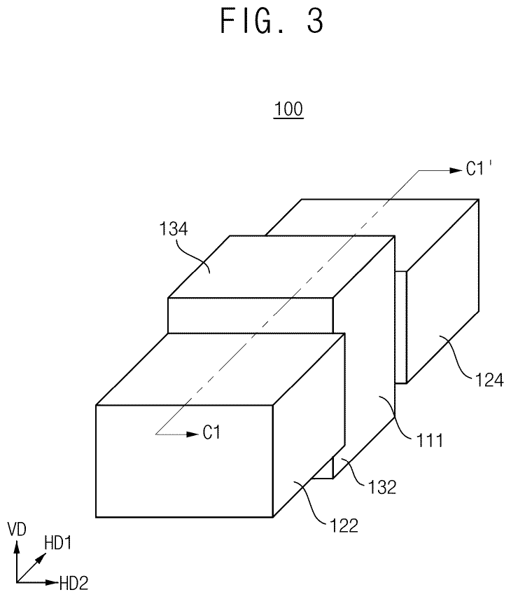

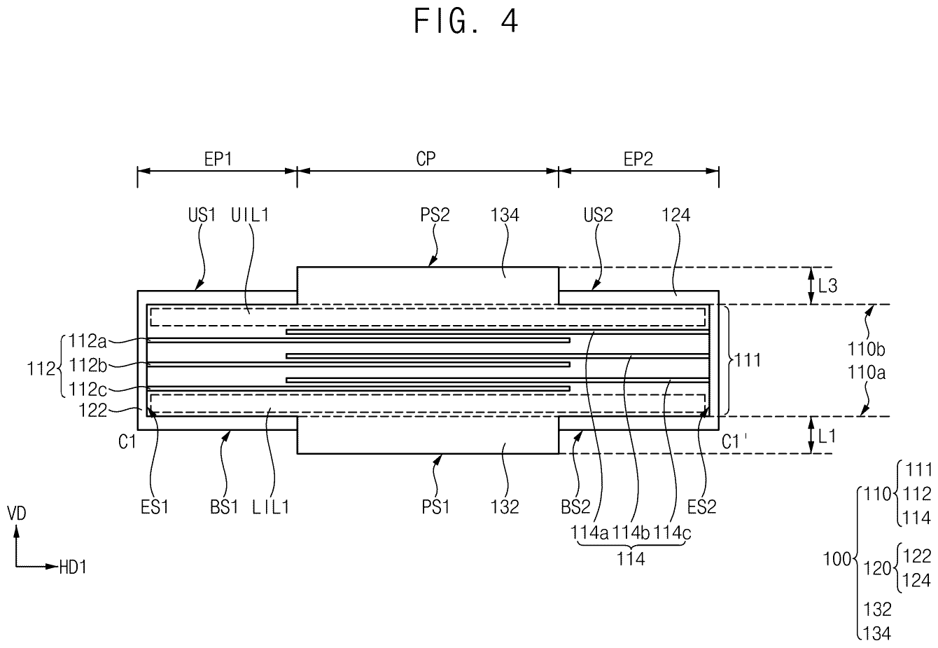

FIG. 1 is a cross-sectional view illustrating a semiconductor package in accordance with an example embodiment. FIG. 2 is an enlarged cross-sectional view illustrating portion ‘M1’ in FIG. 1. FIG. 3 is a perspective view illustrating a capacitor in FIG. 1. FIG. 4 is a cross-sectional view taken along the line C1-C1′ in FIG. 3.

Referring to FIGS. 1 to 4, a semiconductor package 10 may include a substrate structure 20 having a first mounting region MR1 and a second mounting region MR2, at least one semiconductor chip 30 mounted on the first mounting region MR1 of the substrate structure 20, and a double electrode capacitor 100 mounted on the second mounting region MR2 of the substrate structure 20. In addition, the semiconductor package 10 may further include a plurality of external connecting members 27 for electrically connecting the substrate structure 20 and an external device, and a plurality of first conductive connecting members 37 for electrically connecting the substrate structure 20 and the at least one semiconductor chip 30. Further, the semiconductor package 10 may further include a solder layer SL for connecting the substrate structure 20 and the double electrode capacitor 100.

In some example embodiments, the substrate structure 20 may include a plurality of substrate insulating layers 21 and a plurality of substrate wirings 22 provided within the plurality of substrate insulating layers 21. For example, the plurality of substrate insulating layers 21 may include first to fifth insulating layers 21a, 21b, 21c, 21d, 21e that are sequentially stacked. The first insulating layer 21a may be an upper cover layer including a first surface 20a of the substrate structure 20 as an upper surface of the substrate structure, the second insulating layer 21b may be an upper insulating layer, the third insulating layer 21c may be a core layer, the fourth insulating layer 21d may be a lower insulating layer, and the fifth insulating layer 21e may be a lower cover layer including the second surface 20b of the substrate structure 20 as a lower surface of the substrate structure. For example, the plurality of substrate wirings 22 may include first to third internal wirings 22a, 22b, 22c. The first internal wiring 22a may be provided in the second insulating layer 21b, the second internal wiring 22b may be provided in the third insulating layer 21c, and the third internal wiring 22c may be provided in the fourth insulating layer 21d. The first internal wiring 22a, the second internal wiring 22b, and the third internal wiring 22c may include metal wirings and metal vias that are electrically connected to each other.

For example, the substrate structure may be one of various structures for connecting electronic devices, such as a printed circuit board (PCB), a package substrate for connecting to a printed circuit board (PCB), an interposer for connecting a package substrate and a semiconductor chip, a redistribution wiring layer, etc.

The substrate structure 20 may include a plurality of first substrate pads 23 provided in the first mounting region MR1 and a plurality of second substrate pads 24 provided in the second mounting region MR2. The first and second substrate pads 23, 24 may be at least partially exposed from the first surface 20a. The substrate structure 20 may include a plurality of third substrate pads 25 that are at least partially exposed from the second surface 20b. For example, the plurality of first substrate pads 23, the plurality of second substrate pads 24, and the plurality of third substrate pads 25 may be electrically connected to the plurality of substrate wirings 22, respectively.

In addition, the substrate structure 20 may further include the plurality of first external connecting members 27 provided on the plurality of third substrate pads 25, respectively. For example, the plurality of first substrate pads 23, the plurality of second substrate pads 24, the plurality of third substrate pads 25, and the plurality of first external connecting members 27 may include a conductive metal material for electrical connection.

Although several substrate pads are illustrated in the figures, it will be understood that example embodiments are not limited thereto. Accordingly, the number, sizes, arrangements, shapes, etc. of the substrate pads may be changed.

In some example embodiments, the at least one semiconductor chip 30 may have a first surface 30a and a second surface 30b opposite to the first surface 30a. For example, the first surface may be an active surface in which circuit patterns are formed, and the second surface may be an inactive surface. The at least one semiconductor chip 30 may include a plurality of chip pads 33 that are at least partially exposed from the first surface 30a. In addition, the at least one semiconductor chip 30 may further include the plurality of first conductive connecting members 37 provided on the plurality of chip pads 33, respectively.

For example, the plurality of chip pads 33 and the plurality of first conductive connecting members 37 may include a conductive metal material for electrical connection.

For example, the at least one semiconductor chip may include a logic chip including a logic circuit. The logic chip may be a controller that controls memory chips. For example, the at least one semiconductor chip may include a processor chip such as ASIC or AP (Application Processor) as a host such as CPU, NPU, GPU, or SOC. For example, the at least one semiconductor chip may include volatile memory devices such as DRAM or nonvolatile memory devices such as NAND flash memory.

Although only one semiconductor chip is illustrated in the figures, the semiconductor package may include a semiconductor device including a plurality of semiconductor chips. Although a few chip pads are illustrated in the figures, it will be appreciated that example embodiments are not limited thereto. Accordingly, the number, sizes, arrangements, shapes, etc. of the chip pads may be changed.

For example, the at least one semiconductor chip 30 may be mounted on the first mounting region MR1 of the substrate structure 20 via the plurality of first conductive connecting members 37 that are provided between the plurality of chip pads 33 and the plurality of first substrate pads 23, respectively. However, it will be appreciated that example embodiments are not limited thereto. Accordingly, the arrangement, structures, connection methods, etc. of the substrate structure and the at least one semiconductor chip may be changed.

In some example embodiments, the double electrode capacitor 100 may include a pair of first external electrodes 120 electrically connected the substrate structure 20, a body portion 110 including a plurality of insulating layers 111 disposed between the pair of first external electrodes 120 and a plurality of internal electrodes 112, 114 disposed between the plurality of insulating layers 111 and extending in a horizontal direction so as to at least partially contact a portion of the pair of first external electrodes 120, a lower bump structure 132 protruding downwardly from a lowermost insulating layer LIL1 among the plurality of insulating layers 111 so as to contact the substrate structure 20, and an upper protrusion 134 extending upwardly from an uppermost insulating layer UIL1 among the plurality of insulating layers 111. For example, the double electrode capacitor may be a multi-layer ceramic capacitor (MLCC) that supplies power at a constant level to improve electrical characteristics of the semiconductor package.

The body portion 110 may include a plurality of insulating layers 111 that are sequentially stacked. The body portion 110 may include a central portion CP, and a first end portion EP1 and a second end portion EP2 that are arranged in both sides of the central portion CP that is interposed therebetween. The body portion may include an insulating material. For example, the body portion may include a ceramic material.

The body portion 110 may include a plurality of first internal electrodes 112 extending horizontally so as to be at least partially exposed from a first end surface ES1 of the first end portion EP1 and a plurality of second internal electrodes 114 extending horizontally so as to be at least partially exposed from a second end surface ES2 of the second end surface EP2. For example, the plurality of first internal electrodes 112 may include first to third conductive layers 112a, 112b, 112c that are spaced apart from each other in a vertical direction, and the plurality of second internal electrodes 114 may include fourth to sixth conductive layers 114a, 114b, 114c that are spaced apart from each other in the vertical direction. The first to third conductive layers and the fourth to sixth conductive layers may be alternately arranged from one another.

The pair of first external electrodes 120 may include a first-first external electrode 122 that surrounds the first end portion EP1 and at least partially contacts the plurality of first inner electrodes 112, and a second-first external electrode 124 that surrounds the second end portion EP2 and at least partially contacts the plurality of second inner electrodes 114. For example, the plurality of first inner electrodes 112, the plurality of second inner electrodes 114, the first external electrode 120, and the second external electrode 124 may include a conductive metal material.

The first-first external electrode 122 may have a first surface BS1 as a lower surface that faces the substrate structure 20 and a second surface US1 as an upper surface opposite the first surface BS1. In addition, the second external electrode 124 may have a first surface BS2 as a lower surface that faces the substrate structure 20 and a second surface US2 as an upper surface opposite to the first surface BS2.

The lower bump structure 132 may extend from the lower surface 110a of the body portion 110 in a direction approaching the substrate structure 20 and may be provided on the central portion CP of the body portion 110. For example, the lower bump structure 132 may extend from the lower surface 110a of the body portion 110 so as to contact the first surface 20a (e.g., the upper surface of the substrate structure 20).

The body portion 110 may include the lowermost insulating layer LIL1 among the plurality of insulating layers. The lower bump structure 132 may protrude downward from the lowermost insulating layer LIL1 to contact the substrate structure 20. For example, the lowermost insulating layer LIL1 may include the lower surface 110a of the body portion 110. The lower bump structure 132 may extend from the lower surface 110a of the lowermost insulating layer LIL1 to the first surface 20a (e.g., the upper surface of the substrate structure 20).

The upper protrusion 134 may extend from the upper surface 110b of the body portion 110 in a direction away from the substrate structure 20 and may be provided on the central portion CP of the body portion 110. For example, the upper protrusion 134 may extend upward from the upper surface 110a of the body portion 110.

The body portion 110 may include the uppermost insulating layer UIL1 among the plurality of insulating layers. The upper bump structure (or alternatively, upper protrusion) 134 may protrude upward from the uppermost insulating layer UIL1. For example, the uppermost insulating layer UIL1 may include the upper surface 110b of the body portion 110. The upper bump structure (or alternatively, upper protrusion) 134 may extend upward from then upper surface 110a of the uppermost insulating layer UIL1.

The double electrode capacitor 100 may be mounted on the second mounting region MR2 of the substrate structure 20 via solder layers SL that are interposed between the first-first and second-first external electrodes 122, 124 and the plurality of second substrate pads 24, respectively. For example, the solder layer may include a solder paste for electrical connection and physical connection between the substrate structure 20 and the double electrode capacitor 100.

Each of the solder layers SL may have a first bonding surface CS1 that contacts at least one of the first-first and second-first external electrodes 122, 124 and a second bonding surface CS2 that contacts the plurality of second substrate pads 24.

A length in the vertical direction of the lower bump structure 132 may have a first distance L1. For example, the first distance may be a distance from the lower surface 110a of the body portion 110 (e.g., the lower surface of the lowermost insulating layer LIL1) to a first protruding surface PS1 of the lower bump structure 132. The first distance may be equal to a distance from the lower surface 110a of the body portion 110 (e.g., the lower surface of the lowermost insulating layer LIL1) to the first surface 20a of the substrate structure 20. Accordingly, because the lower bump structure 132 is in contact with the substrate structure 20, the double electrode capacitor 100 may be supported by the first lower bump structure 132.

A distance from the lower surface 110a of the body portion 110 (e.g., the lower surface of the lowermost insulating layer LIL1) to each of the second bonding surfaces CS2 of the solder layers SL may be a second distance. For example, the second distance may be the same as the first distance.

However, it will be appreciated that example embodiments are not limited thereto. Accordingly, the magnitude relationship between the first distance and the second distance may be changed. For example, when the plurality of second substrate pads 24 protrude upwardly more than the uppermost insulating layer 21a of the substrate structure 21, the first distance may be greater than the second distance. In contrast, when the uppermost insulating layer 21a of the substrate structure 21 protrudes upwardly more than the plurality of second substrate pads 24, the first distance may be smaller than the second distance.

A length in the vertical direction of the upper protrusion 134 may have a third distance L3. For example, the third distance may be a distance from the upper surface 110b of the body portion 110 (e.g., the upper surface of the uppermost insulating layer UIL1) to a second protrusion surface PS2 of the upper protrusion 134. For example, the third distance may be the same as the first distance. However, it will be appreciated that example embodiments are not limited thereto. Accordingly, the magnitude relationship between the first distance and the third distance may be changed.

As mentioned above, the semiconductor package 10 may include the substrate structure 20 having the first mounting region MR1 and the second mounting region MR2, the at least one semiconductor chip 30 mounted on the first mounting region MR1 of the substrate structure 20, and the double electrode capacitor 100 mounted on the second mounting region MR2 of the substrate structure 20.

The double electrode capacitor may include the pair of first external electrodes 120 electrically connected to the substrate structure 20, the body portion 110 including the plurality of insulating layers 111 disposed between the pair of first external electrodes 120 and the plurality of internal electrodes 112, 114 arranged between the plurality of insulating layers 111, the lower bump structure 132 protruding downward in the vertical direction from the lowermost insulating layer LIL1 among the plurality of insulating layers 111, and the upper protrusion 134 protruding upward in the vertical direction from the uppermost insulating layer UIL1 among the plurality of insulating layers 111. The lower bump structure 132 may be in contact with the substrate structure 20.

Accordingly, the double electrode capacitor may be supported by the lower bump structure. Thus, the lower bump structure may reduce or prevent a bending force from being applied to the double electrode capacitor, and furthermore, the lower bump structure may reduce or prevent a crack from occurring in the double electrode capacitor.

In addition, the vertical extension length of the upper protrusion 134 may be the same as the vertical extension length of the lower bump structure 132.

Accordingly, when the double electrode capacitor 100 is mounted on the substrate structure 20, there is no need to distinguish the upper protrusion 134 and the lower bump structure 132, so that the efficiency of the mounting process may be increased. Even if the double capacitor is mounted upside down, the upper protrusion 134 may come into contact with the substrate structure 20 to perform the same role of the lower bump structure 132.

Hereinafter, a method of manufacturing the semiconductor package of FIG. 1 will be described.

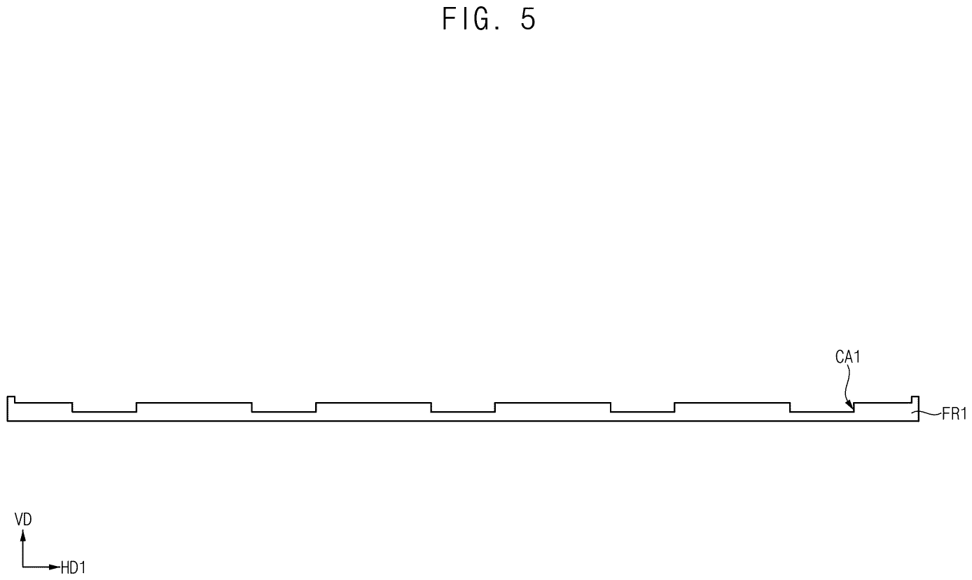

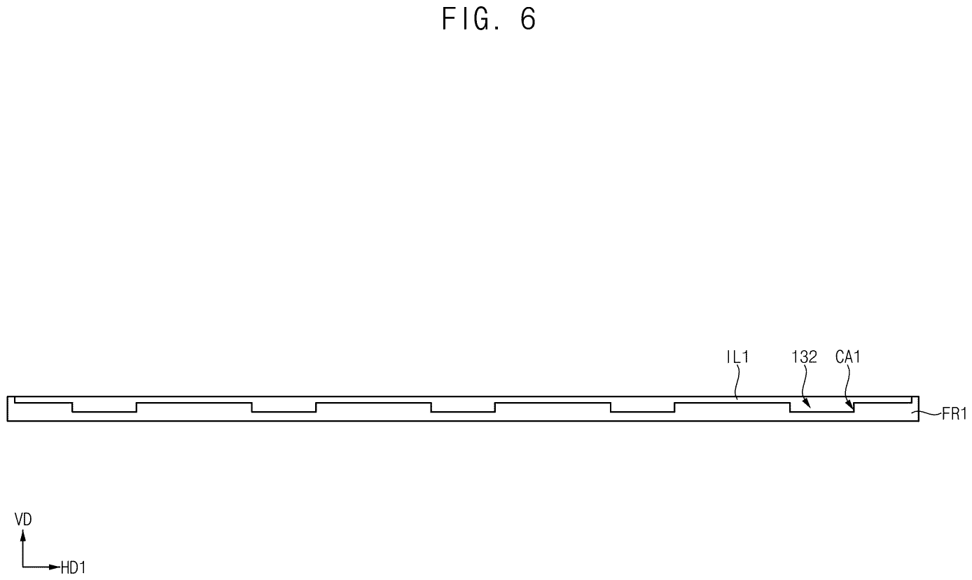

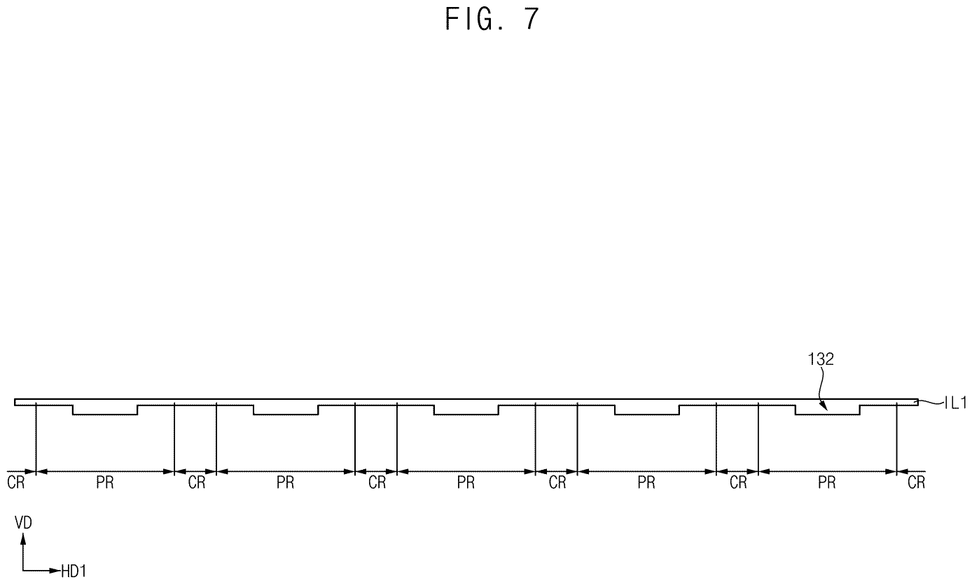

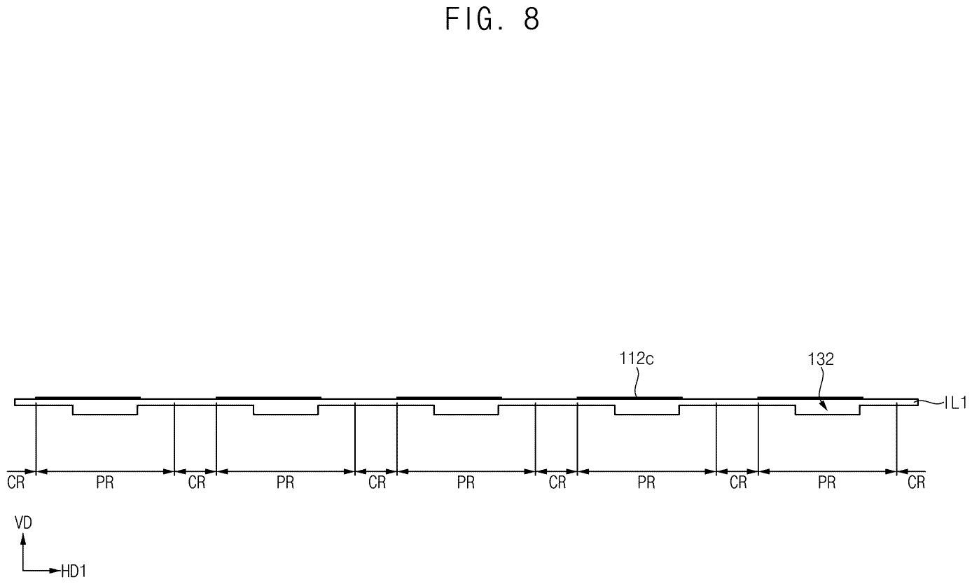

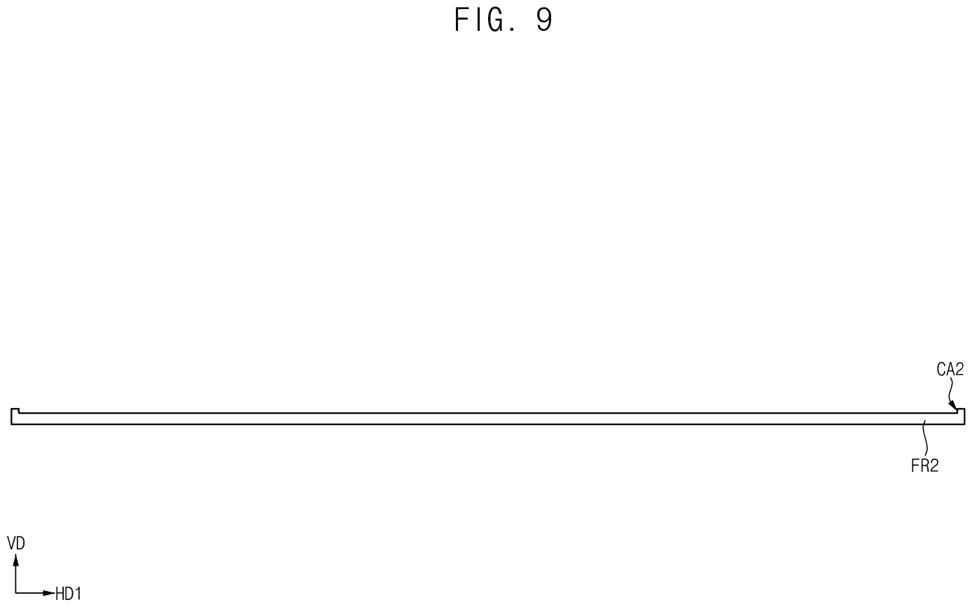

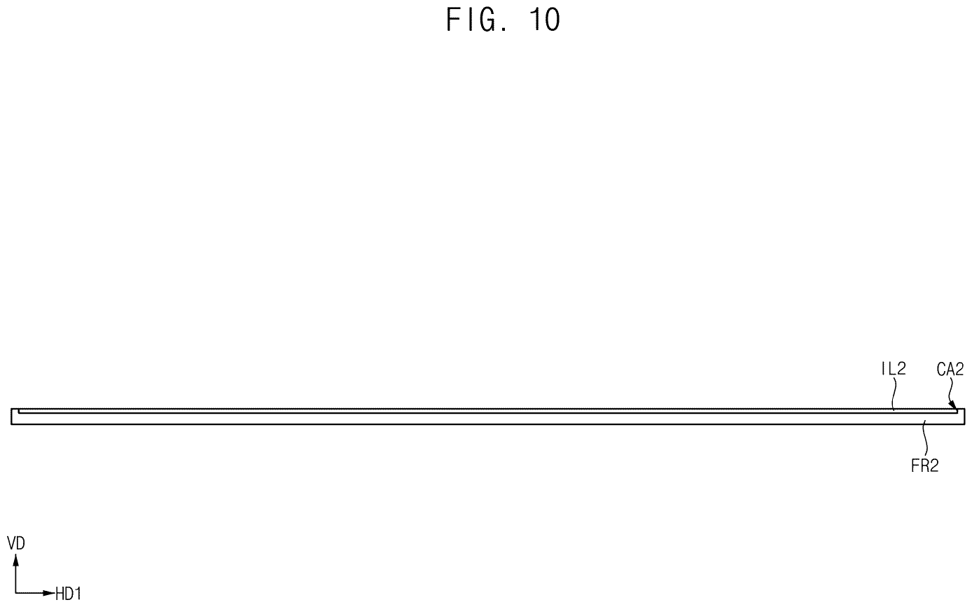

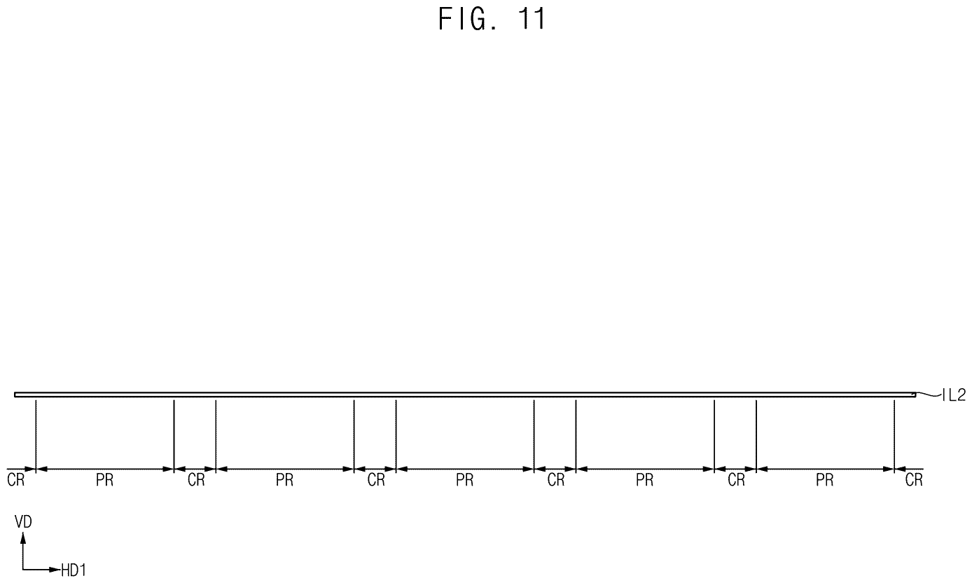

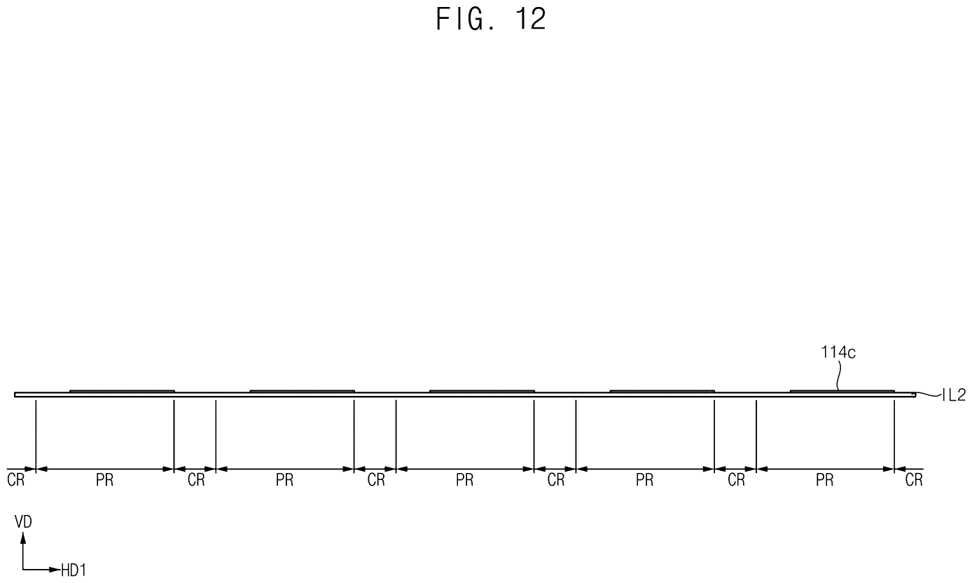

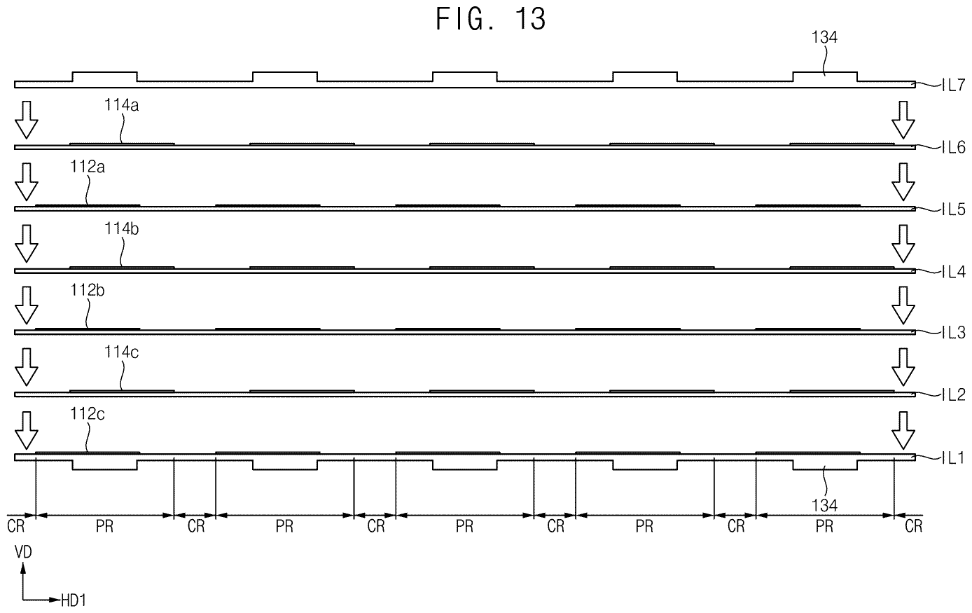

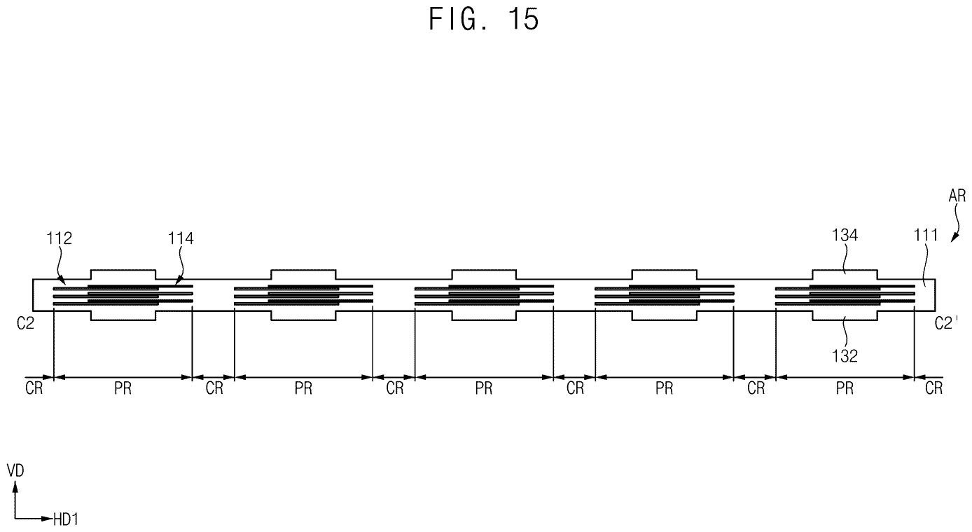

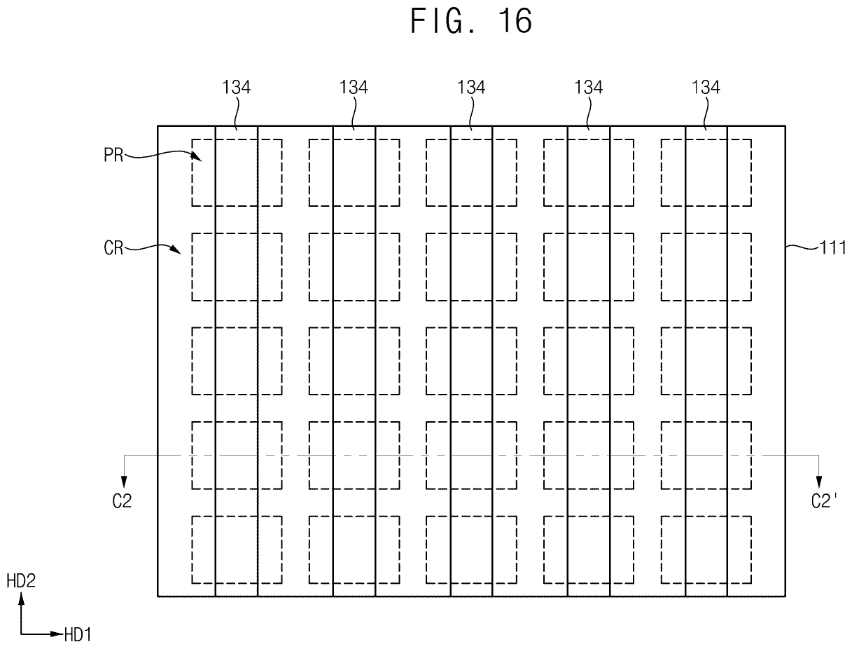

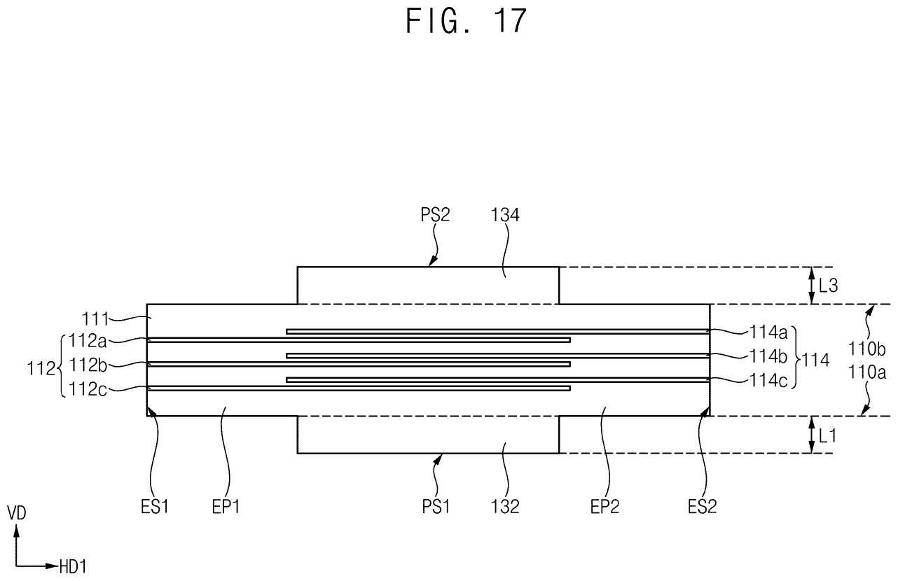

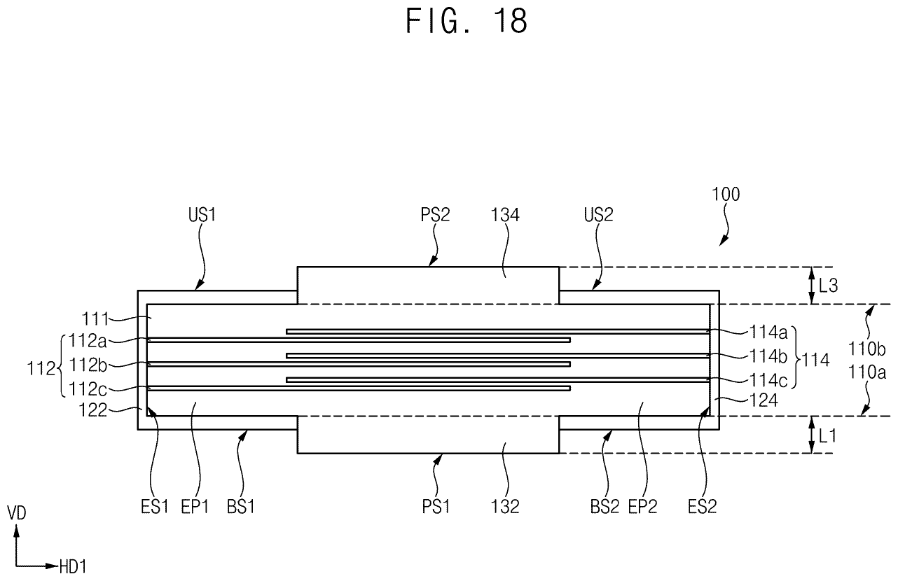

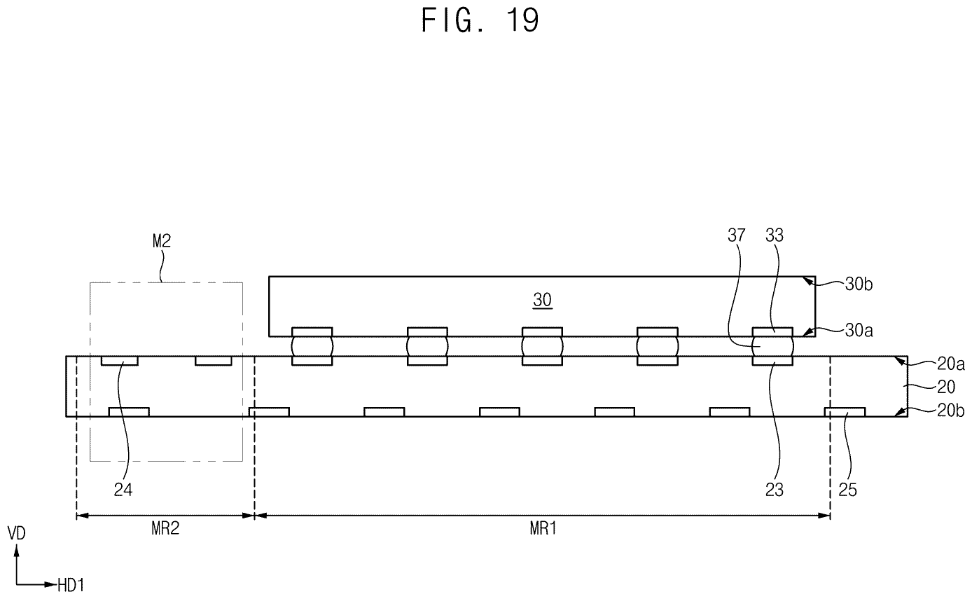

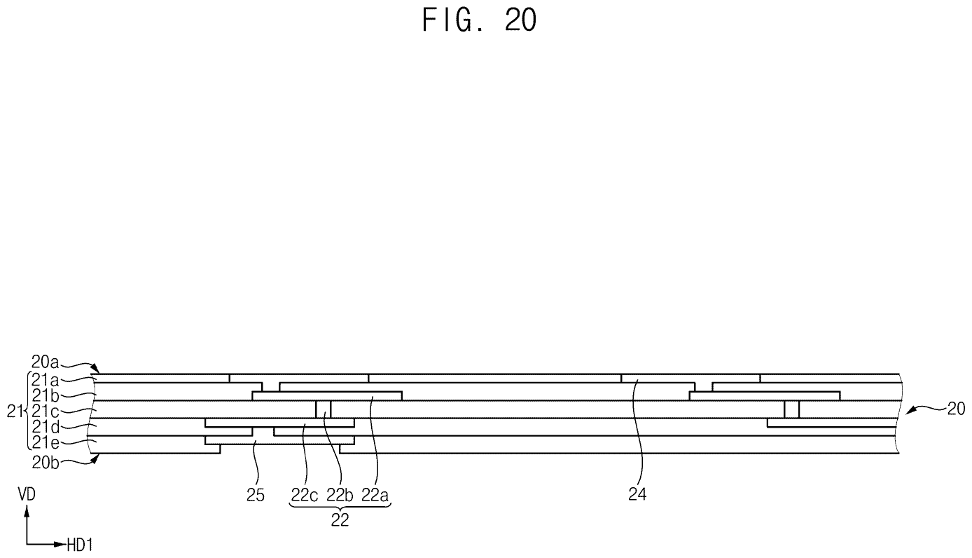

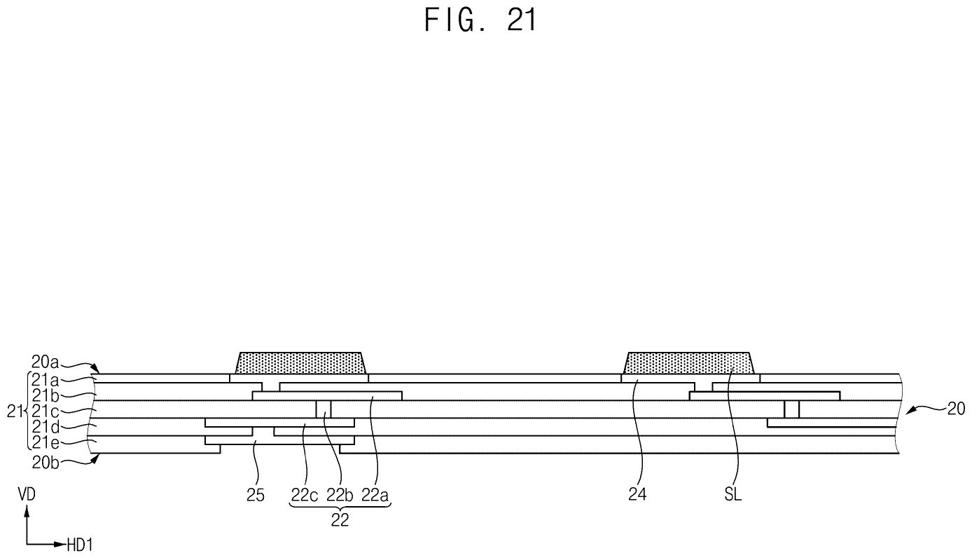

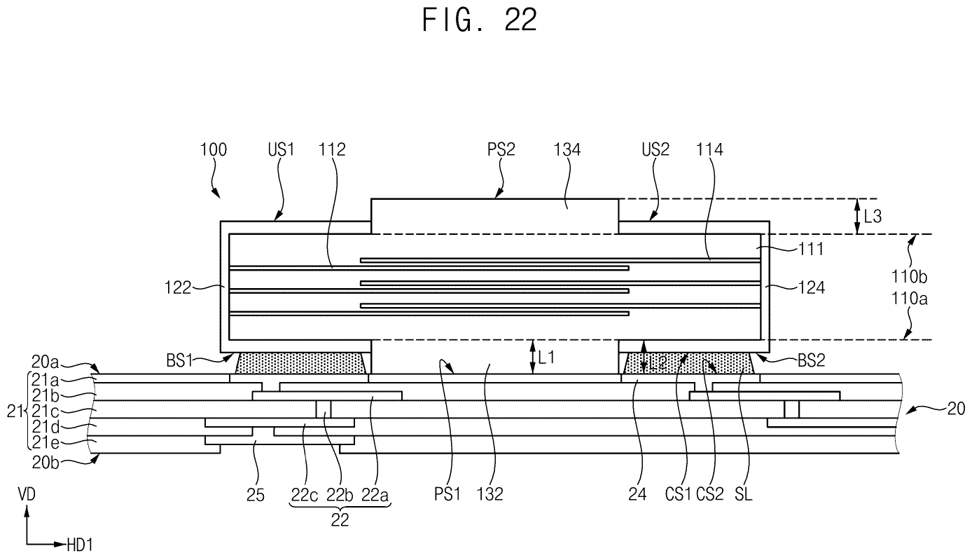

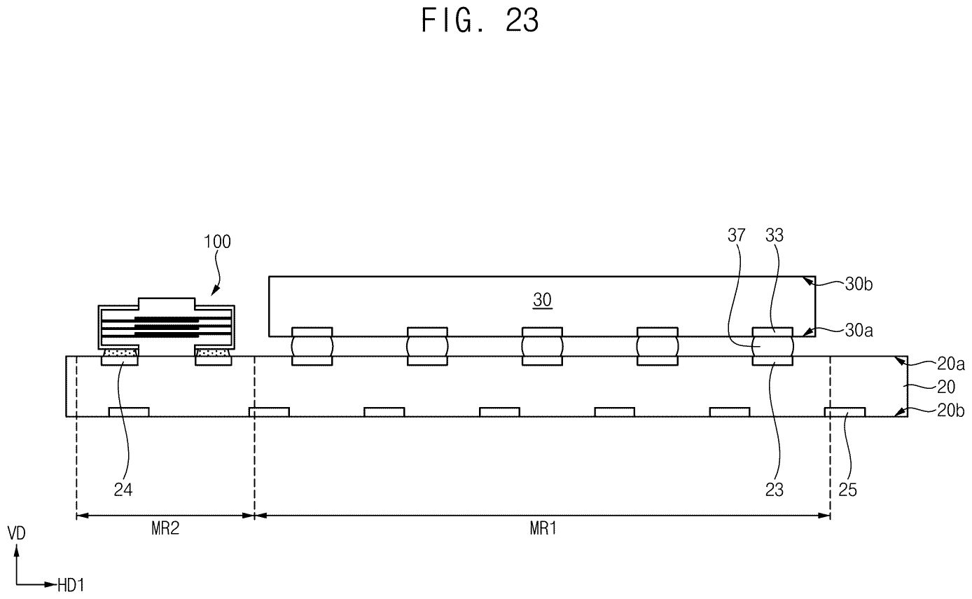

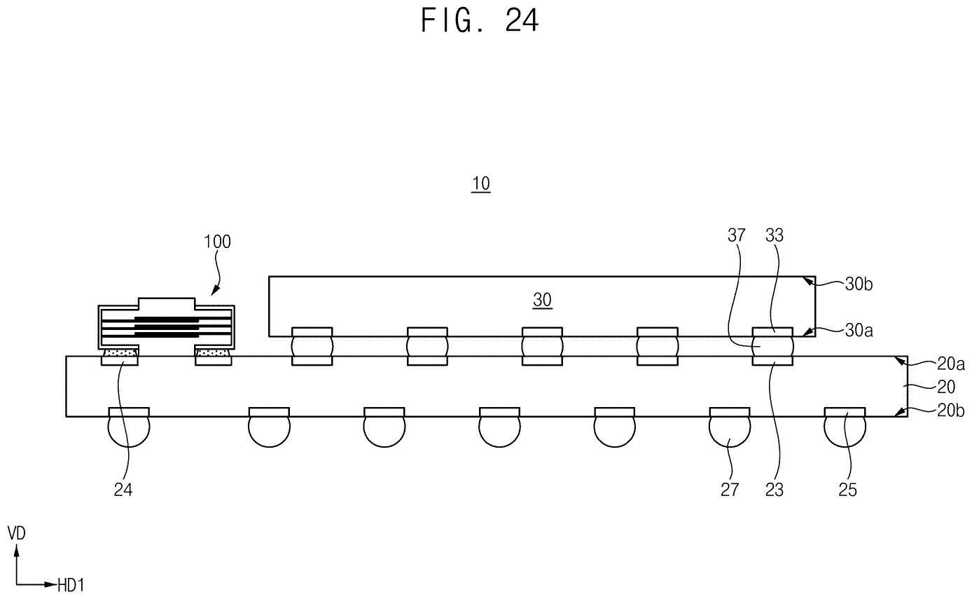

FIGS. 5 to 8 are views illustrating processes of forming a lowermost insulating layer and an uppermost insulating layer of a capacitor in accordance with an example embodiment. FIGS. 9 to 12 are views illustrating processes of forming an intermediate insulating layer of the capacitor in accordance with an example embodiment. FIGS. 13 to 16 are views illustrating processes of forming a capacitor array including a plurality of capacitors by combining the formed insulating layers. FIG. 15 is a cross-sectional view taken along the line C2-C2′ in FIG. 16. FIGS. 17 and 18 are views illustrating processes of cutting the capacitor array to form individual capacitors and of forming external electrodes by a plating process. FIGS. 19 to 23 are views illustrating processes of providing a substrate structure and mounting the capacitor and at least one semiconductor chip on the substrate structure. FIG. 24 is a view illustrating a process of attaching external connecting members on the substrate structure to complete a semiconductor package.

The semiconductor package manufactured by the manufacturing process illustrated in FIGS. 5 to 24 is substantially the same as the semiconductor package described with reference to FIGS. 1 to 4, and therefore, the same components are indicated by the same reference numerals, and repeated descriptions of the same components are omitted.

Referring to FIGS. 5 to 8, a first insulating layer IL1 having a plurality of protrusions may be formed. For example, the first insulating layer may include a plurality of element regions PR and a cutting region CR dividing the plurality of element regions PR. For example, the element region may be a region where capacitors to be described later are formed, and the cutting region may be a region to be removed by a cutting process, as will be described later. For example, the first insulating layer may be a lowermost insulating layer having the plurality of protrusions.

In particular, a first frame FR1 including a plurality of first cavities CA1 for forming a plurality of lower bump structures may be provided. An insulating material may be coated onto the first frame FR1 and the insulating material may be hardened to form a first insulating layer IL1 that has a lower bump structure 132 in each of a plurality of element regions PR.

Then, a plurality of conductive layers including a third conductive layer 112c may be formed on the plurality of element regions PR of the first insulating layer IL1, respectively.

Referring to FIGS. 9 to 12, a second insulating layer IL2 may be formed as an intermediate insulating layer. For example, the second insulating layer may include a plurality of element regions PR and a cutting region CR dividing the plurality of element regions PR. For example, the element region may be a region where capacitors to be described later are formed, and the cutting region may be a region to be removed by a cutting process, as will be described later.

For example, a second frame FR2 including a second cavity CA2 may be provided. An insulating material may be coated onto the second frame FR2 and the insulating material may be hardened to form a second insulating layer IL2.

Then, a plurality of conductive layers including a sixth conductive layer 114c may be formed on the plurality of element regions PR of the second insulating layer IL2.

Referring to FIGS. 13 to 16, a plurality of insulating layers IL1, IL2, IL3, IL4, IL5, IL6, IL7 may be formed, and a capacitor array including a plurality of capacitors may be formed by combining the plurality of insulating layers IL1, IL2, IL3, IL4, IL5, IL6, IL7.

For example, the plurality of insulating layers IL1, IL2, IL3, IL4, IL5, IL6, IL7 may include the first insulating layer IL1 including the lowermost insulating layer and the plurality of lower bump structures, a seventh insulating layer IL7 including an uppermost insulating layer and a plurality of upper protrusions, and second to sixth insulating layers IL2, IL3, IL4, IL5, IL6 as intermediate insulating layers.

The seventh insulating layer IL7 may include an upper protrusion 134 provided in each of the plurality of element regions PR. The seventh insulating layer IL7 may be formed by processes the same as or substantially similar to the processes of forming the first insulating layer IL1 described with reference to FIGS. 5 to 8. Accordingly, the processes of forming the seventh insulating layer IL7 will be omitted. For example, the seventh insulating layer may be the uppermost insulating layer having the plurality of upper protrusions.

The third insulating layer IL3 may include a second conductive layer 112b provided on the element region, the fourth insulating layer IL4 may include a fifth conductive layer 114b provided on the element region, the fifth insulating layer IL5 may include a first conductive layer 112a provided on the element region, and the sixth insulating layer IL6 may include a fourth conductive layer 114a provided on the element region. The third to sixth insulating layers IL3, IL4, IL5, IL6 may be formed by processes the same as or substantially similar to the processes of forming the second insulating layer IL2 described with reference to FIGS. 9 to 12. Accordingly, the processes of forming the third to sixth insulating layers IL3, IL4, IL5, IL6 will be omitted.

The first to seventh insulating layers IL1, IL2, IL3, IL4, IL5, IL6, IL7 may be sequentially stacked. Then, the first to seventh insulating layers IL1, IL2, IL3, IL4, IL5, IL6, IL7 may be pressed using a lower pressing device LC and an upper pressing device UC, to form a capacitor array AR in which a plurality of capacitors are integrally coupled to each other.

For example, the capacitor array AR may include a plurality of insulating layers 111 extending in a horizontal direction, internal electrodes 112, 114 provided within the element regions PR of the plurality of insulating layers 111, a lower bump structure 132 extending in the horizontal direction and protruding downward from the plurality of insulating layers 111, and an upper protrusion 134 extending in the horizontal direction and protruding upward from the plurality of insulating layers 111.

Referring to FIGS. 17 and 18, the capacitor array AR may be cut along the cutting region CR to form individual capacitors. Then, both end portions of each of the individual capacitors may be plated to form external electrodes, to complete a double electrode capacitor 100.

For example, the cutting region CR may be removed to individualize the plurality of element regions PR of the capacitor array AR. For example, the individualized capacitor may have a first end portion EP1 and a second end portion EP2 through which the plurality of internal electrodes 112, 114 are at least partially exposed. Additionally, the individualized capacitor may have the lower bump structure 132 and the upper protrusion 134 provided between the first end portion EP1 and the second end portion EP2.

Then, a plating process may be performed to form a first-first external electrode 122 that surrounds the first end portion EP1 of the individualized capacitor and a second-first external electrode 124 may be formed on the second end portion EP2 of the individualized capacitor, thereby completing the double electrode capacitor 100.

Because the double electrode capacitor is the same as or substantially similar to the double electrode capacitor 100 described with reference to FIGS. 1 to 4, a repeated description of the same components is omitted.

Referring to FIGS. 19 to 23, a substrate structure 20 having a first mounting region MR1 and a second mounting region MR2 may be provided, at least one semiconductor chip 30 may be mounted on the first mounting region MR1 of the substrate structure 20, and the double electrode capacitor 100 may be mounted on the second mounting region MR2 of the substrate structure 20.

For example, the at least one semiconductor chip 30 may be mounted on the first mounting region MR1 of the substrate structure 20 via a plurality of first conductive connecting members 37 that are provided between first substrate pads 23 of the substrate structure 20 and chip pads 33 of at least one semiconductor chip 30, respectively. For example, the substrate structure 20 and at least one semiconductor chip 30 may be electrically and physically connected to each other through a solder reflow process.

Then, a solder layer SL including a solder paste may be provided on a plurality of second substrate pads 24 of the substrate structure 20, and the double electrode capacitor 100 may be mounted on the second mounting region MR2 of the substrate structure 20 through the solder layer SL that is provided between the plurality of second substrate pads 24 and the first external electrodes 122, 124 of the double electrode capacitor 100, respectively. For example, the substrate structure 20 and the double electrode capacitor 100 may be electrically and physically connected to each other through a solder reflow process.

At this time, by using an adsorption nozzle of a pick-up device, a vacuum may be applied to an upper portion of the double electrode capacitor 100, so that the double electrode capacitor 100 may be adsorbed onto the adsorption nozzle. Then, the pick-up device may attach the double electrode capacitor 100 onto the second mounting region MR2 such that the first external electrodes 122, 124 of the double electrode capacitor 100 and the plurality of second substrate pads 24 are connected to each other via the solder layer SL. Then, the vacuum of the adsorption nozzle may be released.

Here, because the lower bump structure 132 of the double electrode capacitor 100 is in contact with the substrate structure 20, the double electrode capacitor 100 may be supported by the lower bump structure 132. Accordingly, during the mounting process, a repulsive force may be applied to the first external electrodes 122, 124 in both end portions of the double electrode capacitor 100 as well as the lower bump structure 132 located at a central portion of the double electrode capacitor 100, so that the lower bump structure may reduce or prevent a bending force from being applied to the double electrode capacitor. Further, the lower bump structure may reduce or prevent cracks from occurring in the double electrode capacitor due to the bending force.

Referring to FIG. 24, external connecting members 27 may be attached on a plurality of third substrate pads 24 of the substrate structure 20, to complete the semiconductor package 10.

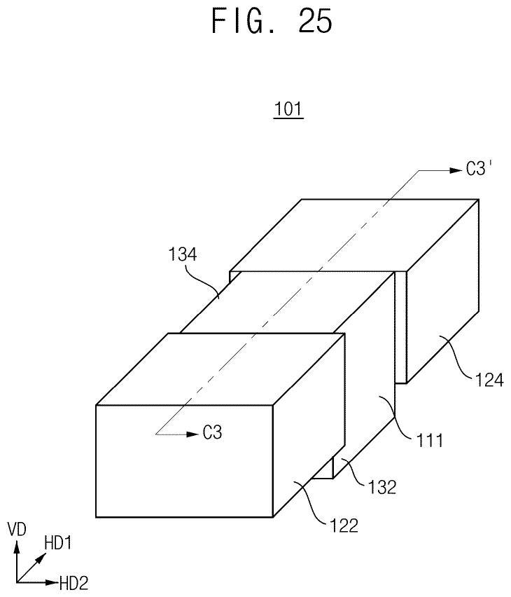

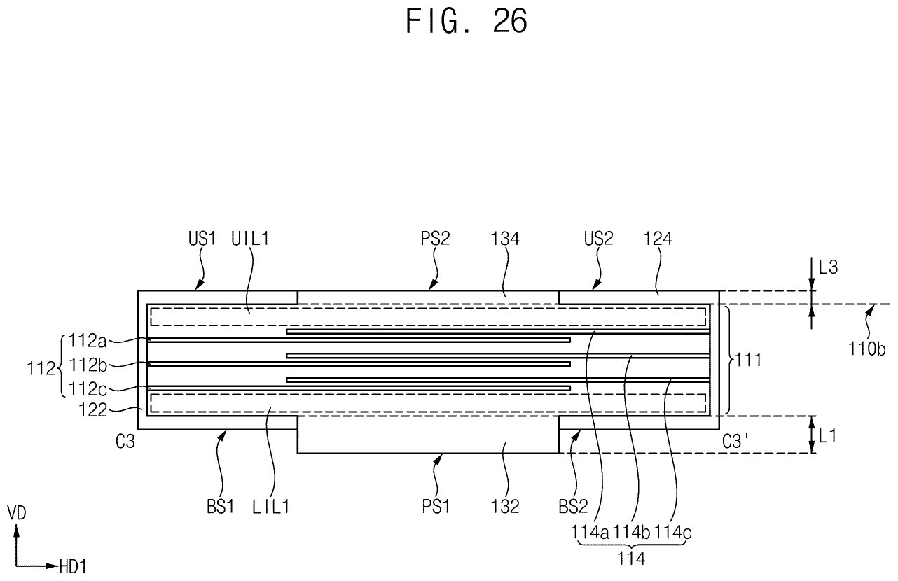

FIG. 25 is a perspective view illustrating a capacitor in accordance with an example embodiment. FIG. 26 is a cross-sectional view taken along the line C3-C3′ in FIG. 25.

The double electrode capacitor illustrated in FIGS. 25 and 26 is the same as or substantially similar to the double electrode capacitor described with reference to FIGS. 1 to 4 except for an upper protrusion 134, and thus, the same components are indicated by the same reference numerals, and repeated descriptions of the same components are omitted.

In some example embodiments, a double electrode capacitor 101 may include a pair of first external electrodes 120 electrically connected to a substrate structure 20, a body portion 110 including a plurality of insulating layers 111 disposed between the pair of first external electrodes 120 and a plurality of internal electrodes 112, 114 disposed between the plurality of insulating layers 111 and extending in a horizontal direction so as to at least partially contact a portion of the pair of first external electrodes 120, a lower bump structure 132 protruding downwardly from a lowermost insulating layer LIL1 among the plurality of insulating layers 111 so as to contact the substrate structure 20, and an upper protrusion 134 extending upwardly from an uppermost insulating layer UIL1 among the plurality of insulating layers 111.

The upper protrusion 134 may have a second protrusion surface PS2 as an upper surface. In addition, a first-first external electrode 122 may have a second surface US1 as an upper surface, and a second-first external electrode 124 may have a second surface US2 as an upper surface.

The upper surface (e.g., second protrusion surface PS2) of the upper protrusion 134 and the upper first and second surfaces (e.g., first and second surfaces US1, US2) of the pair of external electrodes 120 may be positioned on the same plane. For example, the upper protrusion 134 may protrude upwardly from an upper surface 110b of the body portion 110 such that the second protrusion surface PS2 of the upper protrusion 134, the second surface US1 of the first-first external electrode 122, and the second surface US2 of the second-first external electrode 124 are located on the same plane.

As mentioned above, the double electrode capacitor 101 may have the upper protrusion 134.

The upper protrusion 134 may protrude upwardly from the uppermost insulating layer UIL1 of the body portion 110 such that the upper surface (e.g., second protrusion surface PS2) of the upper protrusion 134 and the upper surfaces (e.g., first and second surfaces US1, US2) of the pair of external electrodes 120 are located on the same plane.

Accordingly, in a pick-up process using an adsorption nozzle, the upper surface (e.g., second protrusion surface PS2) of the upper protrusion 134 and the upper surfaces (e.g., first and second surfaces US1, US2) of the pair of external electrodes 120 may provide a flat suction area to which the adsorption nozzle is attached. Thus, the double electrode capacitor 101 may provide a relatively wide adsorption surface US1, US2, PS2, thereby increasing the stability of the pick-up process.

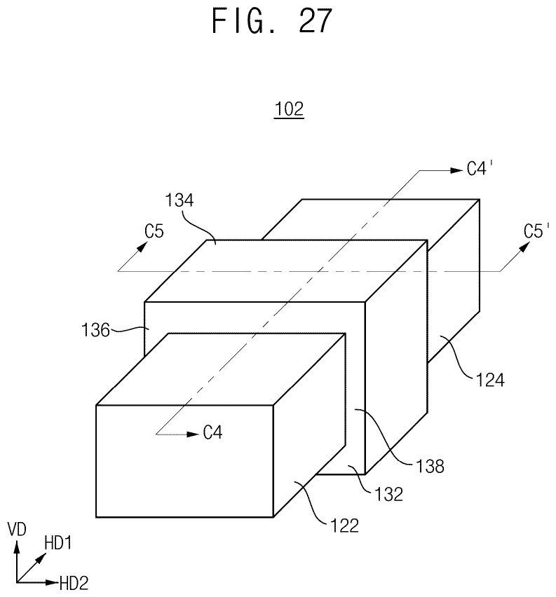

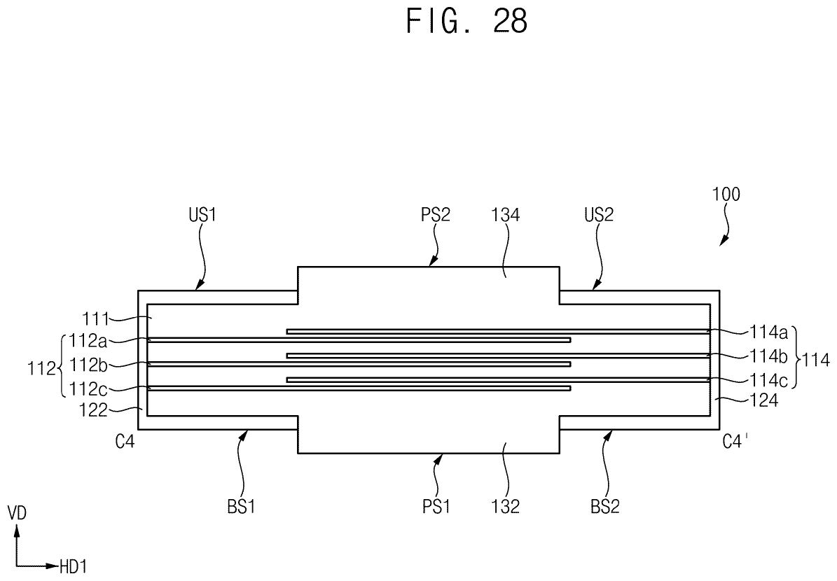

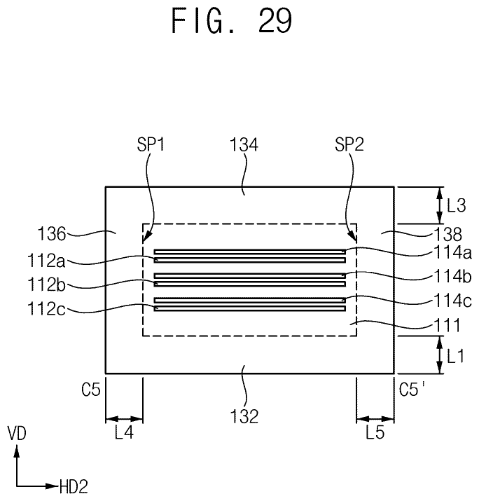

FIG. 27 is a perspective view illustrating a capacitor in accordance with an example embodiment. FIG. 28 is a cross-sectional view taken along the line C4-C4′ in FIG. 27. FIG. 29 is a cross-sectional view taken along the line C5-C5′ in FIG. 27.

The double electrode capacitor illustrated in FIGS. 27 to 29 is the same as or substantially similar to the double electrode capacitor described with reference to FIGS. 1 to 4 except for side protrusions 136, 138, and thus, the same components are indicated by the same reference numerals, and repeated descriptions of the same components are omitted.

In some example embodiments, the double electrode capacitor 102 may include a pair of first external electrodes 120 electrically connected to a substrate structure 20, a body portion 110 including a plurality of insulating layers 111 disposed between the pair of first external electrodes 120, and a plurality of internal electrodes 112, 114 disposed between the plurality of insulating layers 111 and extending in a horizontal direction so as to at least partially contact a portion of the pair of first external electrodes 120, a lower bump structure 132 protruding downwardly from a lowermost insulating layer LIL1 among the plurality of insulating layers 111 so as to contact the substrate structure 20, and an upper protrusion 134 extending upwardly from an uppermost insulating layer UIL1 among the plurality of insulating layers 111.

The double electrode capacitor 102 may further include a first side protrusion 136 that protrudes horizontally from a first side portion SP1 of the body portion 110 and a second side protrusion 138 that protrudes horizontally from a second side portion SP2 of the body portion 110.

A length in a vertical direction of the lower bump structure 132 may have a first distance L1. In addition, a length in a vertical direction of the upper protrusion 134 may have a third distance L3. A length in a horizontal direction of the first side protrusion 136 may have a fourth distance L4. In addition, a length in the horizontal direction of the second side protrusion 138 may have a fifth distance L5. For example, the first distance, the second distance, the third distance, and the fourth distance may be the same.

However, it will be appreciated that example embodiments are not limited thereto. Accordingly, the lengths of the lower bump structure 132, the upper protrusion 134, the first side protrusion 136, and the second side protrusion 138 may be changed.

As mentioned above, the double electrode capacitor 102 may include the lower bump structure 132, the upper protrusion 134, the first side protrusion 136, and the second side protrusion 138.

The vertical extension length of the lower bump structure, the vertical extension length of the upper protrusion, the horizontal extension length of the first side protrusion, and the horizontal extension length of the second side protrusion may be the same.

Accordingly, when the double electrode capacitor 102 is mounted on the substrate structure 20, there is no need to distinguish the lower bump structure 132, the upper protrusion 134, the first side protrusion 136, and the second side protrusion 138 on the substrate structure 20, so that the efficiency of the mounting process may be increased.

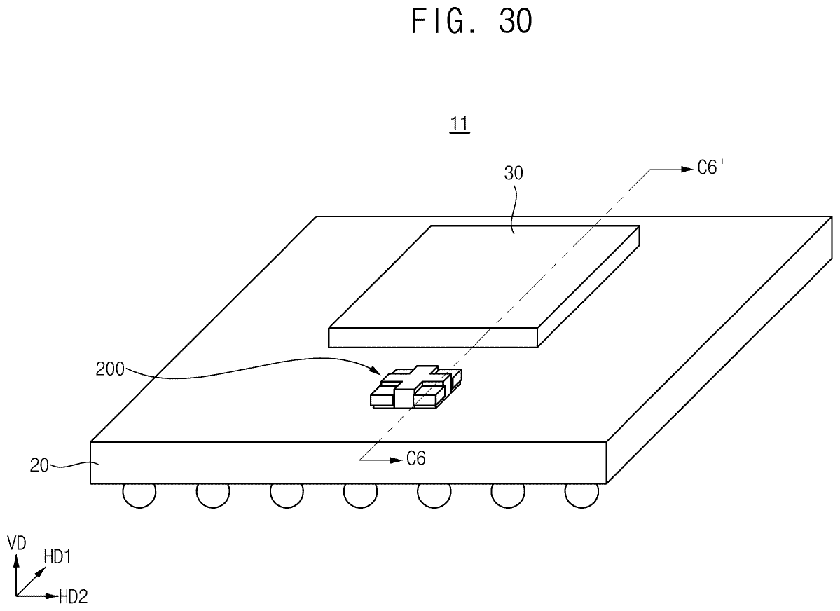

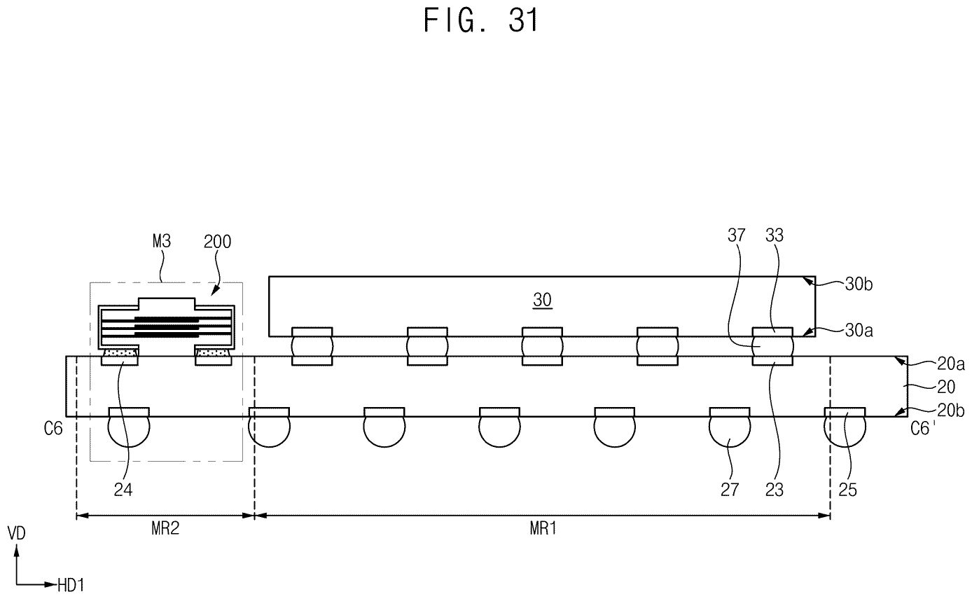

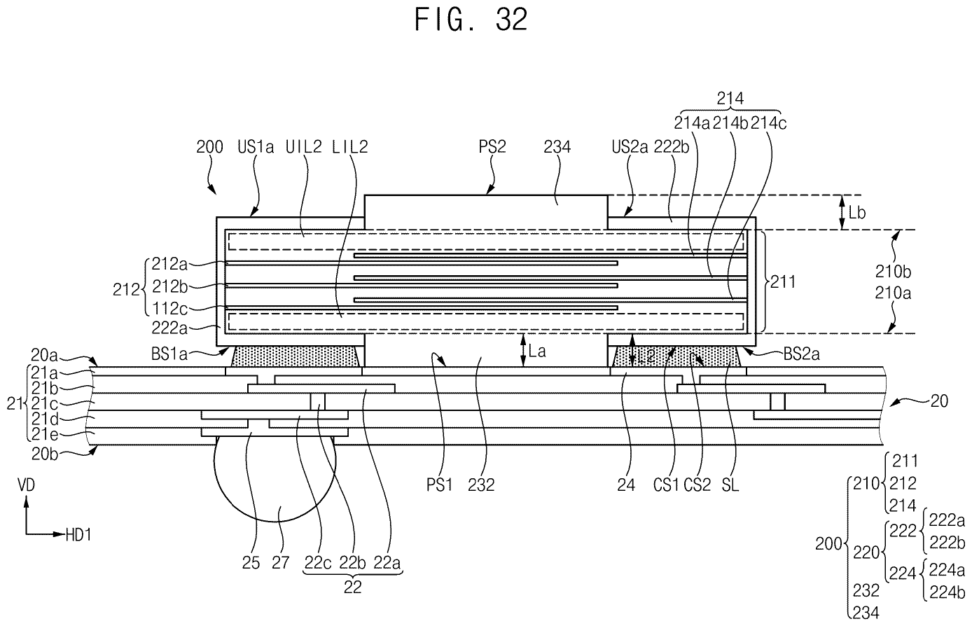

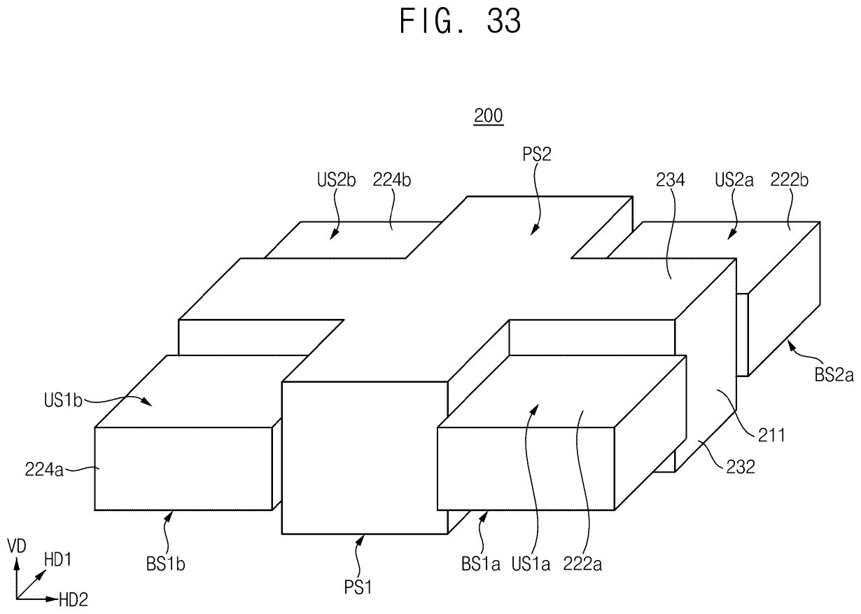

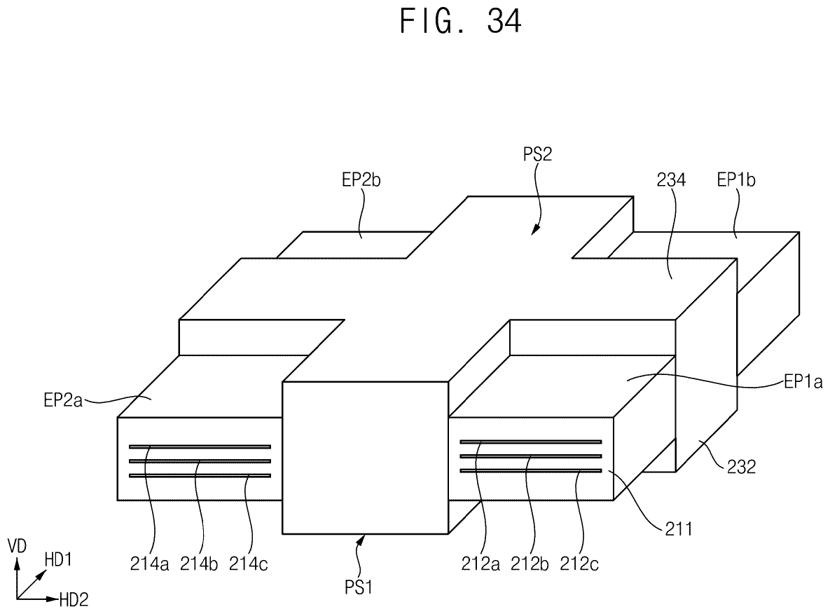

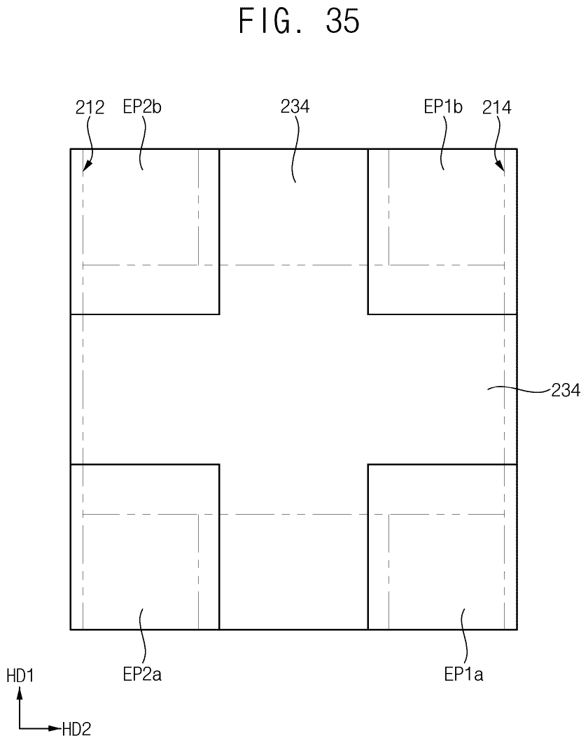

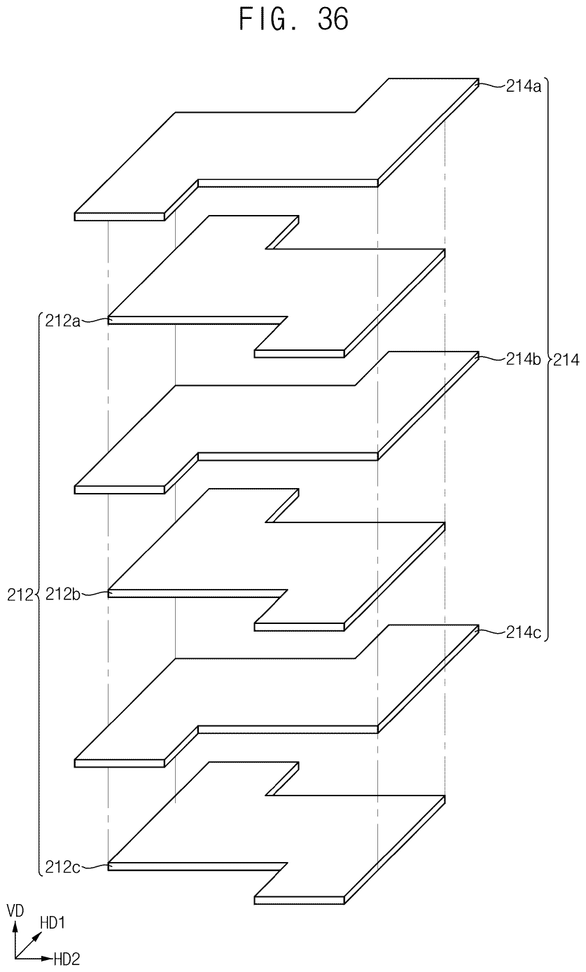

FIG. 30 is a perspective view illustrating a semiconductor package in accordance with an example embodiment. FIG. 31 is a cross-sectional view taken along the line C6-C6′ in FIG. 30. FIG. 32 is an enlarged cross-sectional view illustrating portion ‘M3’ in FIG. 31. FIG. 33 is a perspective view illustrating the capacitor of FIG. 30. FIG. 34 is a perspective view illustrating the capacitor of FIG. 30, wherein electrodes are omitted. FIG. 35 is a plan view illustrating the capacitor of FIG. 30, wherein electrodes are omitted. FIG. 36 is a perspective view illustrating internal electrodes of the capacitor of FIG. 30.

The semiconductor package illustrated in FIGS. 30 to 36 is the same as or substantially similar to the semiconductor package described with respect to FIGS. 1 to 4 except for a quadruple electrode capacitor 200, and thus, the same components are indicated by the same reference numerals, and repeated descriptions of the same components are omitted.

Referring to FIGS. 30 to 36, a semiconductor package 11 may include a substrate structure 20 having a first mounting region MR1 and a second mounting region MR2, at least one semiconductor chip 30 mounted on the first mounting region MR1 of the substrate structure 20, and a quadruple electrode capacitor 200 mounted on the second mounting region MR2 of the substrate structure 20.

In some example embodiments, the quadruple electrode capacitor 200 may include an electrode portion 220 having a pair of second external electrodes 222 and a pair of third external electrodes 224 that are electrically connected to the substrate structure 20, a body portion 210 including a plurality of insulating layers 211 disposed between the pair of second external electrodes 222 and the pair of third external electrodes 224 and a plurality of internal electrodes 212, 214 disposed within the plurality of insulating layers 211, a lower bump structure 232 protruding downwardly from a lowermost insulating layer LIL2 among the plurality of insulating layers 211 to contact the substrate structure 20, and an upper protrusion 234 protruding upwardly from an uppermost insulating layer UIL2 among the plurality of insulating layers 211. For example, the quadruple electrode capacitor may be a multi-layer ceramic capacitor (MLCC) that supplies power at a constant level to improve electrical characteristics of the semiconductor package.

The body portion 210 may include the plurality of insulating layers 211 that are sequentially stacked. The body portion 210 may include a first end portion EP1a and a second end portion EP1b that are spaced apart from each other in a first horizontal direction, and may include a third end portion EP2a and a fourth end portion EP2b that are spaced apart from each other in the first horizontal direction. The third end portion EP2a may be spaced apart from the first end portion EP1a in a second horizontal direction that is different from the first horizontal direction, and the fourth end portion EP2b may be spaced apart from the second end portion EP1b in the second horizontal direction. For example, the body portion may have a square shape when viewed in plan view. The first to fourth end portions may be positioned at four corners of the square shape, respectively.

The body portion 210 may include a plurality of first internal electrodes 212 extending horizontally so as to be at least partially exposed from the first end portion EP1a and the fourth end EP2b, and a plurality of second internal electrodes 214 extending horizontally so as to be at least partially exposed from the second end portion EP1b and the third end portion EP2a. For example, the plurality of first internal electrodes 212 may include first, second and third conductive layers 212a, 212b, 212c that are vertically spaced apart from each other, and the plurality of second internal electrodes 214 may include fourth, fifth and sixth conductive layers 214a, 214b, 214c that are vertically spaced apart from each other. The first to third conductive layers and the fourth to sixth conductive layers may be alternately arranged.

Referring again to FIG. 36, for example, each of the first, second and third conductive layers may have a shape like ‘ [symbol] ’ when viewed in plan view, and each of the fourth, fifth and sixth conductive layers may have a shape like ‘ [symbol] ’ when viewed in plan view.

However, it will be appreciated that example embodiments are not limited thereto. Accordingly, the shapes, sizes, arrangements, etc. of the first to sixth conductive layers may be changed.

The electrode portion 220 may include the pair of second external electrodes 222 that are spaced apart from each other in the second horizontal direction and the pair of third external electrodes 224 that are spaced apart from each other in the second horizontal direction.

The pair of second external electrodes 222 may include a first-second external electrode 222a that surrounds the first end portion EP1a and at least partially contacts the plurality of first internal electrodes 212, and a second-second external electrode 222b that surrounds the second end portion EP1b and at least partially contacts the plurality of second internal electrodes 214.

The pair of third external electrodes 224 may include a first-third external electrode 224a that surrounds the third end portion EP2a and at least partially contacts the plurality of second internal electrodes 214, and a second-third external electrode 224b that surrounds the fourth end portion EP2b and at least partially contacts the plurality of first internal electrodes 212.

For example, the plurality of first internal electrodes 212 may extend from the first end portion EP1a to the fourth end portion EP2b so as to at least partially contact the first-second external electrode 222a and the second-third external electrode 224b, respectively. The plurality of first internal electrodes 212 may be exposed from the first end portion EP1a and the fourth end portion EP2b. Additionally, the plurality of second inner electrodes 214 may extend from the second end portion EP1b to the third end portion EP2a so as to at least partially contact the second-second external electrode 222b and the first-third external electrode 224a, respectively. The plurality of second inner electrodes 214 may be exposed from the second end portion EP1b and the third end portion EP2a.

For example, the plurality of first inner electrodes 212, the plurality of second inner electrodes 214, the first-second external electrode 222a, the second-second external electrode 222b, the first-third external electrode 224a, and the second-third external electrode 224b may include a conductive metal material.

The first-second external electrode 222a may have a first surface BS1a as a lower surface that faces the substrate structure 20 and a second surface US1a as an upper surface opposite the first surface BS1a. The second-second external electrode 222b may have a first surface BS2a as a lower surface that faces the substrate structure 20 and a second surface US2a as an upper surface opposite the first surface BS2a. In addition, the first-third external electrode 224a may have a first surface BS1b as a lower surface that faces the substrate structure 20 and a second surface US1b as an upper surface opposite the first surface BS1b. The second-third external electrode 224b may have a first surface as a lower surface BS2b that faces the substrate structure 20 and a second surface US2b as an upper surface opposite to the first surface.

The lower bump structure 232 may be provided on a lower surface 210a of the body portion 210 so as to be provided between the pair of second external electrodes 222 and the pair of third external electrodes 224.

The lower bump structure 232 may extend from the lower surface 210a of the body portion 210 in a direction approaching the substrate structure 20. For example, the lower bump structure may extend from the lower surface 210a of the body portion 210 to the first surface 20a (e.g., the upper surface of the substrate structure 20).

The body portion 210 may include a lowermost insulating layer LIL2 among the plurality of insulating layers. The lower bump structure 232 may protrude downward from the lowermost insulating layer LIL2 so as to come into contact with the substrate structure 20. For example, the lowermost insulating layer LIL2 may include the lower surface 210a of the body portion 210. The lower bump structure 232 may extend from the lower surface 210a of the lowermost insulating layer LIL2 to the first surface 20a (e.g., the upper surface of the substrate structure 20). The upper protrusion 234 may be provided on an upper surface 210b of the body portion 210 so as to be provided between the pair of second external electrodes 222 and the pair of third external electrodes 224.

The upper protrusion 234 may extend from the upper surface 210b of the body portion 210 in a direction away from the substrate structure 20. For example, the upper protrusion may extend upward from the upper surface 210a of the body portion 210.

The body portion 210 may include an uppermost insulating layer UIL2 among the plurality of insulating layers. The upper bump structure (or alternatively, upper protrusion) 234 may protrude upward from the uppermost insulating layer UIL2. For example, the uppermost insulating layer UIL2 may include the upper surface 210b of the body portion 210. The upper bump structure (or alternatively, upper protrusion) 234 may extend upward from the upper surface 210a of the uppermost insulating layer UIL2.

The quadruple electrode capacitor 200 may be mounted on the second mounting region MR2 of the substrate structure 20 via solder layers SL that are respectively provided on the pair of first and second external electrodes 222, 224 and the plurality of second substrate pads 24. For example, the solder layer may include a solder paste for electrical connection and physical connection between the substrate structure 20 and the quadruple electrode capacitor 200.

Each of the solder layers SL may have a first bonding surface CS1 that contacts at least one of the first-second, second-second, first-third and second-third external electrodes 222a, 222b, 224a, 224b and a second bonding surface CS2 that contacts a plurality of second substrate pads 24.

A vertical length of the lower bump structure 232 may have a first distance La. For example, the first distance may be a distance from the lower surface 210a of the body portion 210 (e.g., the lower surface of the lowermost insulating layer LIL2) to a first protruding surface PS1 of the lower bump structure 232. The first distance may be equal to a distance from the lower surface 210a of the body portion 210 (e.g., the lower surface of the lowermost insulating layer LIL2) to the first surface 20a of the substrate structure 20. Accordingly, because the lower bump structure 232 is in contact with the substrate structure 20, the quadruple electrode capacitor 200 may be supported by the lower bump structure 232.

A distance from the lower surface 210a of the body portion 210 (e.g., the lower surface of the lowermost insulating layer LIL2) to each of the second bonding surfaces CS2 of the solder layers SL may be a second distance. For example, the second distance may be the same as the first distance.

However, it will be appreciated that example embodiments are not limited thereto. Accordingly, the magnitude relationship between the first distance and the second distance may be changed. For example, when the plurality of second substrate pads 24 protrude upwardly more than the uppermost insulating layer 21a of the substrate structure 21, the first distance may be greater than the second distance. In contrast, when the uppermost insulating layer 21a of the substrate structure 21 protrudes upwardly more than the plurality of second substrate pads 24, the first distance may be less than the second distance.

The vertical length of the upper protrusion 234 may have a third distance Lb. For example, the third distance may be a distance from the upper surface 210b of the body portion 210 (e.g., the upper surface of the uppermost insulating layer UIL2) to a second protrusion surface PS2 of the upper protrusion 234. For example, the third distance may be the same as the first distance. However, it will be appreciated that example embodiments are not limited thereto. Accordingly, the magnitude relationship between the first distance and the third distance may be changed.

As mentioned above, the semiconductor package 11 may include the substrate structure 20 having the first mounting region MR1 and the second mounting region MR2, the at least one semiconductor chip 30 mounted on the first mounting region MR1 of the substrate structure 20, and the quadruple electrode capacitor 200 mounted on the second mounting region MR2 of the substrate structure 20. The quadruple electrode capacitor 200 may include the pair of second external electrodes 222 and the pair of third external electrodes 224 electrically connected to the substrate structure 20, the body portion 210 including the plurality of insulating layers 211 arranged between the pair of second external electrodes 222 and the pair of third external electrodes 224 and the plurality of internal electrodes 212, 214 arranged between the plurality of insulating layers 211, the lower bump structure 232 protruding downward from the lowermost insulating layer LIL2 among the plurality of insulating layers 211 to contact the substrate structure 20, and the upper protrusion 234 protruding upward from the uppermost insulating layer UIL2 among the plurality of insulating layers 211.

Accordingly, the quadruple electrode capacitor may be supported by the lower bump structure. Thus, the lower bump structure may reduce or prevent a bending force from being applied to the quadruple electrode capacitor, and further, the lower bump structure may reduce or prevent a crack from occurring in the quadruple electrode capacitor.

In addition, the vertical length of the upper protrusion 234 may be the same as the vertical length of the lower bump structure 232.

Accordingly, when the quadruple electrode capacitor 200 is mounted on the substrate structure 20, there is no need to mount the upper protrusion 234 and the lower bump structure 232 separately on the substrate structure 20 (e.g., there is no difference between the upper protrusion 234 and the lower bump structure 232 in terms of mounting the upper protrusion 234 and the lower bump structure 232 on the substrate structure 20), so that the efficiency of the mounting process may be increased.

Hereinafter, a method of manufacturing the quadruple electrode capacitor of FIG. 30 will be described.

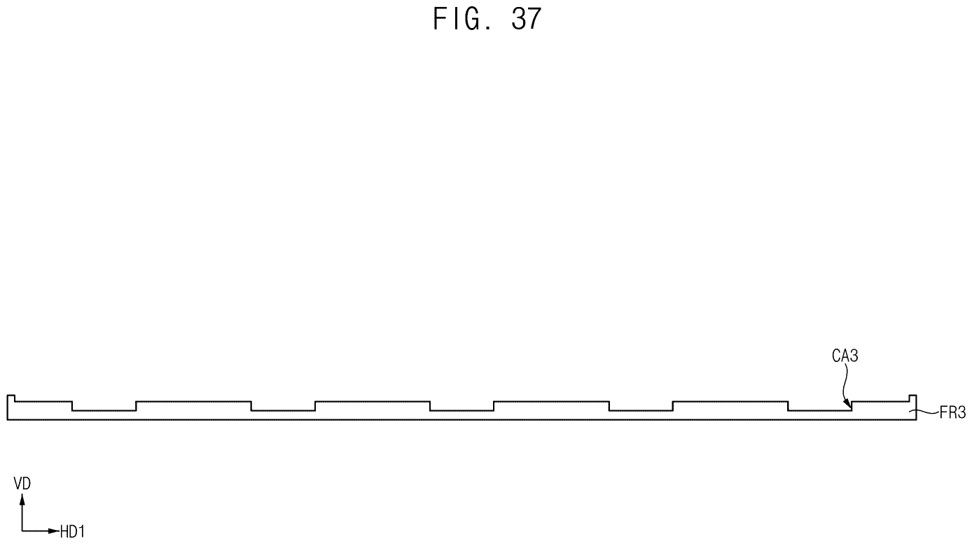

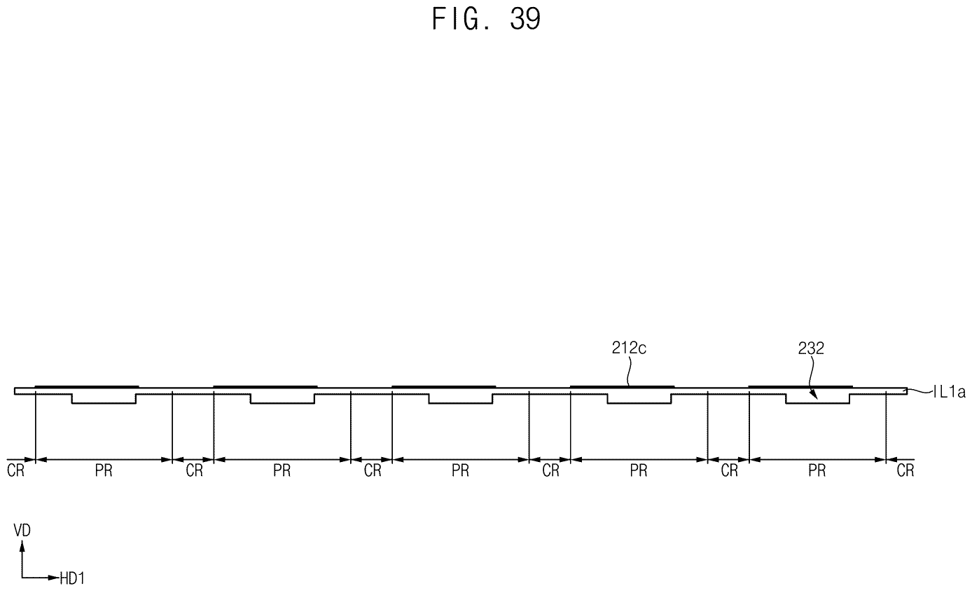

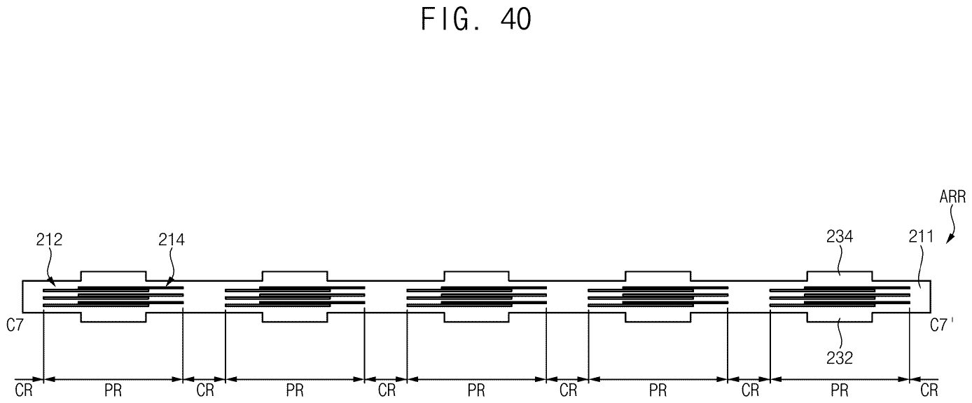

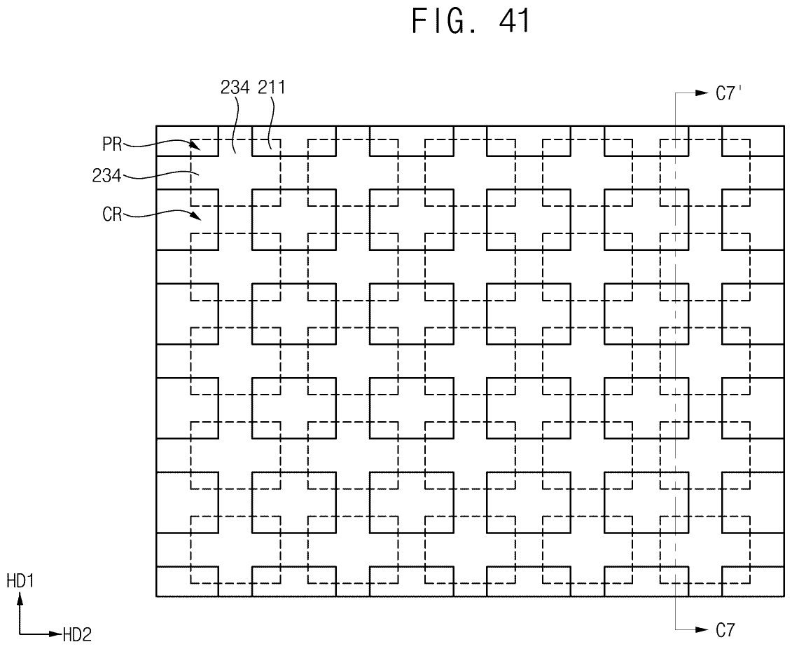

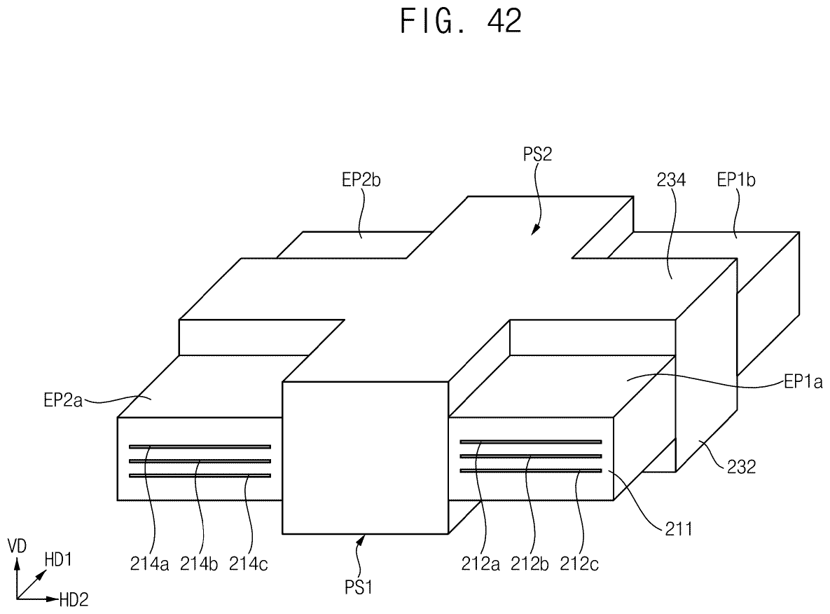

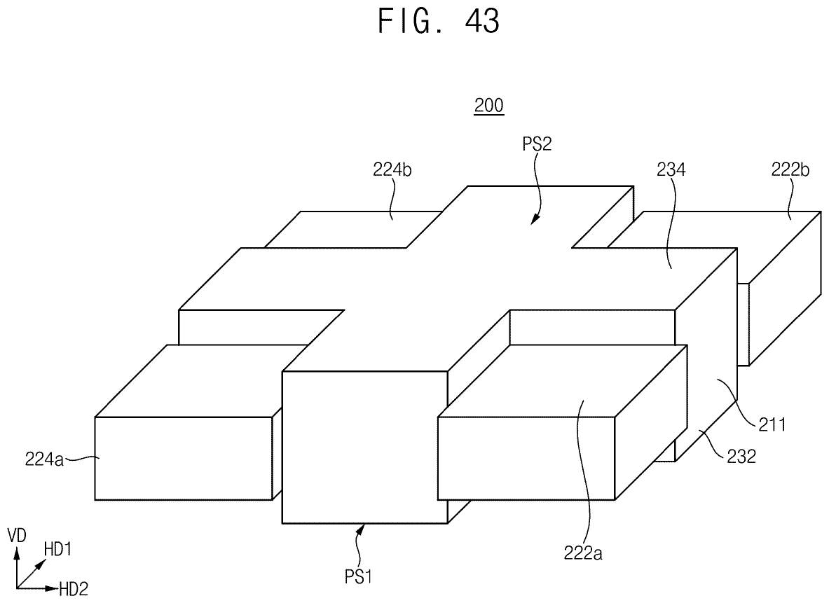

FIGS. 37 to 40 are views illustrating processes of forming insulating layers of a capacitor in accordance with an example embodiment. FIGS. 40 and 41 are views illustrating processes of forming a capacitor array by combining the insulating layers. FIG. 42 is a perspective view illustrating a process of cutting the capacitor array to form an individual capacitor. FIG. 43 is a perspective view illustrating a process of forming a capacitor by a plating process.

The capacitor manufactured by the manufacturing process illustrated in FIGS. 37 to 43 is the same as or substantially similar to the capacitor described with reference to FIGS. 30 to 36, and thus, the same components are indicated by the same reference numerals, and repeated descriptions of the same components are omitted.

Referring to FIGS. 37 to 39, a first insulating layer IL1a may be formed as a lowermost insulating layer having a plurality of protrusions. For example, the first insulating layer may include a plurality of element regions PR and a cutting region CR dividing the plurality of element regions PR. For example, the e he element region may be a region where capacitors to be described later are formed, and the cutting region may be a region to be removed by a cutting process, as will be described later.

For example, a third frame FR3 including a plurality of first cavities CA3 for forming a plurality of lower bump structures may be provided. An insulating material may be coated onto the third frame FR3 and the insulating material may be cured to form a first insulating layer IL1a that has a lower bump structure 232 in each of the plurality of element regions PR.

Then, a plurality of conductive layers including a third conductive layer 212c may be formed on the plurality of element regions PR of the first insulating layer IL1a.

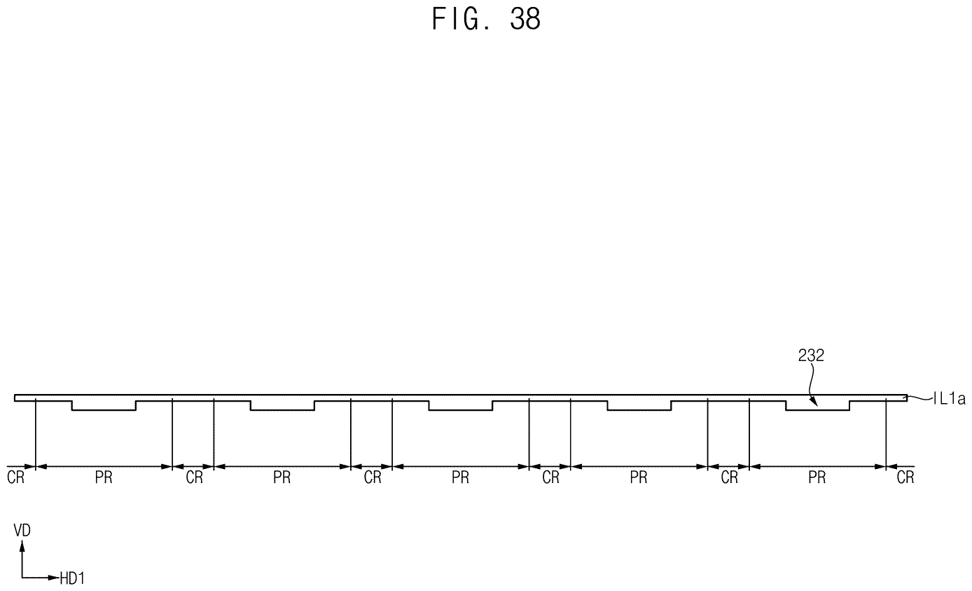

Then, processes the same as or substantially similar to the processes described with reference to FIGS. 9 to 12 may be performed to form a plurality of intermediate insulating layers, and processes the same as or substantially similar to the processes described with reference to FIGS. 37 and 38 may be performed to form an uppermost insulating layer. Thus, a description of the substantially identical process is omitted.

Referring to FIGS. 40 and 41, the lowermost insulating layer, the plurality of intermediate insulating layers, and the uppermost insulating layer may be pressed to form a quadruple electrode capacitor array ARR in which a plurality of capacitors are integrally coupled to each other.

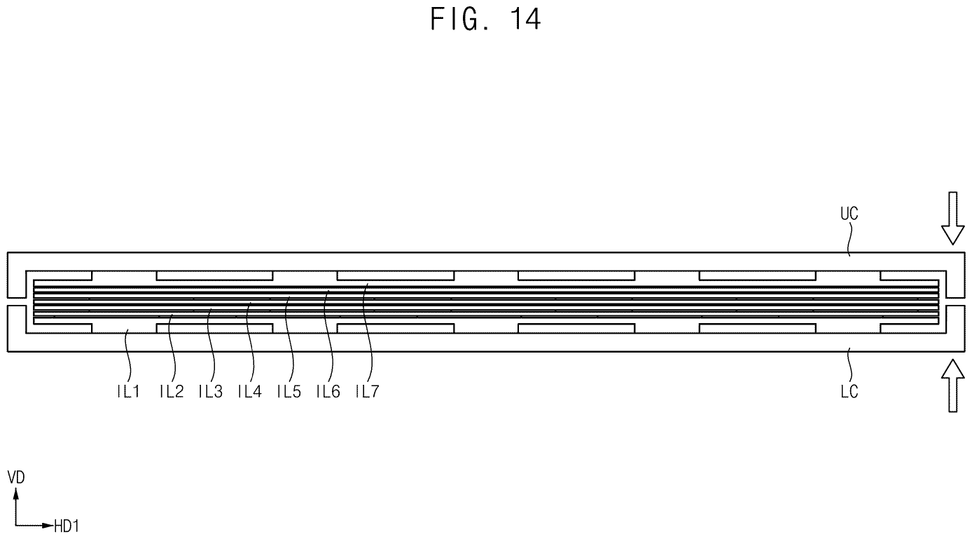

The process of pressing the lowermost insulating layer, the plurality of intermediate insulating layers, and the uppermost insulating layer may be the same as or substantially similar to the process described with reference to FIGS. 13 and 14. Thus, descriptions of the substantially same process steps are omitted.

For example, the quadruple electrode capacitor array ARR may include a plurality of insulating layers 211 extending in a horizontal direction, internal electrodes 212, 214 provided in the element regions PR of the plurality of insulating layers 211, a lower bump structure 232 extending in the horizontal direction and protruding downward from the lowermost insulating layer ILI2 among the plurality of insulating layers 211, and an upper protrusion 234 extending in the horizontal direction and protruding upward from the uppermost insulating layer ULI2 among the plurality of insulating layers 211. For example, the lower bump structure and the upper protrusion of the quadruple electrode capacitor array may have a grid-like shape when viewed in plan view.

Referring to FIGS. 42 and 43, the quadruple electrode capacitor array ARR may be cut along the cutting region CR to form individual capacitors. Then, four end portions EP1a, EP1b, EP2a, EP2b of the individualized capacitor may be plated to form external electrodes to complete the quadruple electrode capacitor 200.

For example, the cutting region CR may be removed to individualize the plurality of element regions PR of the quadruple electrode capacitor array ARR. For example, the individualized capacitor may have the end portions EP1a, EP1b, EP2a, EP2b through which the plurality of internal electrodes 212, 214 are at least partially exposed. Additionally, the individualized capacitor may have the lower bump structure 232 and the upper protrusion 234 provided between the end portions EP1a, EP1b, EP2a, EP2b.

Then, a plating process may be performed to form a first-second external electrode 222a that surrounds the first end portion EP1a of the individualized capacitor, a second-second external electrode 222b that surrounds the second end portion EP1b of the individualized capacitor, a first-third external electrode 224a that surrounds the third end portion EP2a of the individualized capacitor, and a second-third external electrode 224b that surrounds the fourth end portion EP2b of the individualized capacitor, to complete the quadruple electrode capacitor 200.

Because the above quadruple electrode capacitor is the same as or substantially similar to the double electrode capacitor 200 described with reference to FIGS. 30 to 36, a repeated description of the same components is omitted.

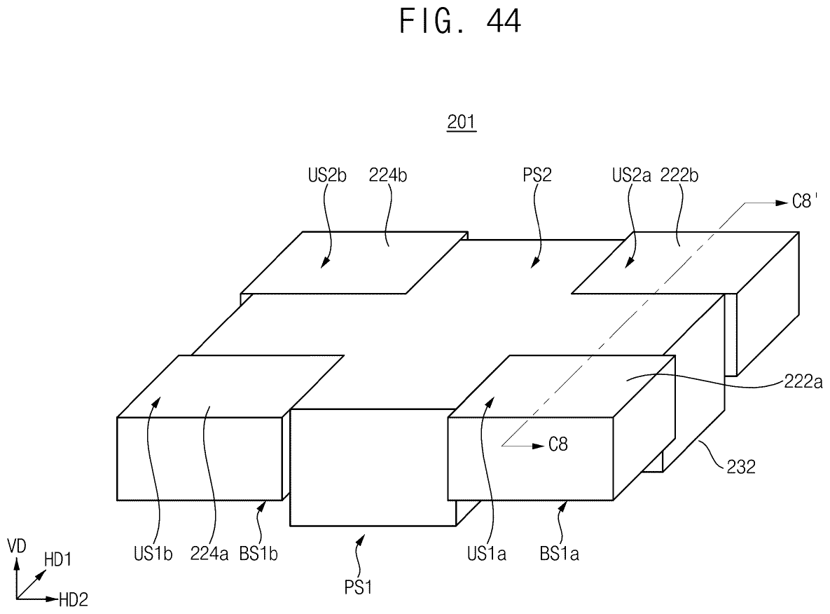

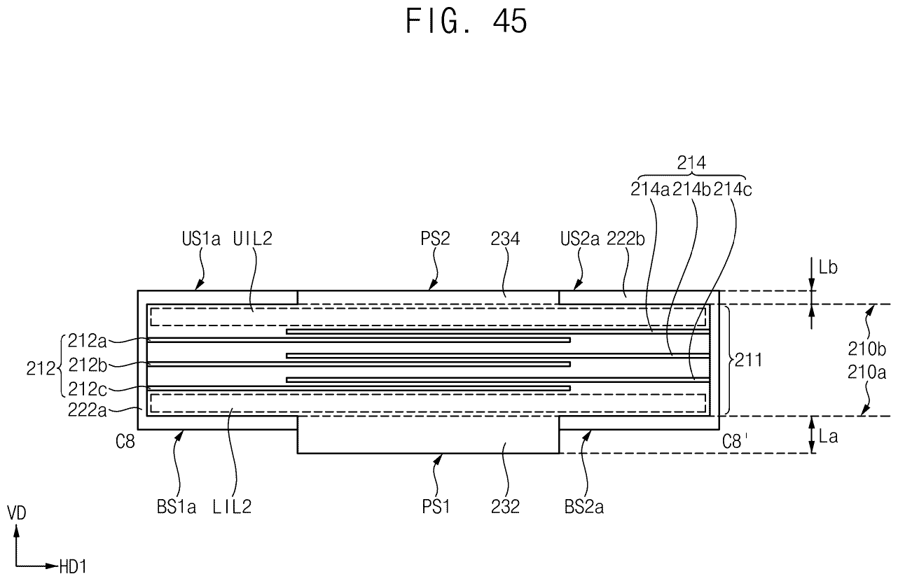

FIG. 44 is a perspective view illustrating a capacitor in accordance with an example embodiment. FIG. 45 is a cross-sectional view taken along the line C8-C8′ in FIG. 43.

The quadruple electrode capacitor illustrated in FIGS. 44 and 45 is the same as or substantially similar to the quadruple electrode capacitors described with reference to FIGS. 30 to 36 except for an upper protrusion 234, and thus, the same components are indicated by the same reference numerals, and repeated descriptions of the same components are omitted.

Referring to FIGS. 44 and 45, a quadruple electrode capacitor 201 may include an electrode portion 220 including a pair of second external electrodes 222 and a pair of third external electrodes 224 electrically connected to a substrate structure 20, a body portion 210 including a plurality of insulating layers 211 disposed between the pair of second external electrodes 222 and the pair of third external electrodes 224 and a plurality of internal electrodes 212, 214 arranged within the plurality of insulating layers 211, a lower bump structure 232 protruding downward from a lowermost insulating layer LIL2 among the plurality of insulating layers 211 to contact the substrate structure 20, and an upper protrusion 234 protruding upward from an uppermost insulating layer UIL2 among the plurality of insulating layers 211.

The upper protrusion 234 may have a second protrusion surface PS2 as an upper surface. In addition, a first-second external electrode 222a may have a first-second surface US1a as an upper surface, a second-second external electrode 222b may have a second-second surface US2a as an upper surface, a first-third external electrode 224a may have a first-third surface US1b as an upper surface, and a second-third external electrode 224b may have a second-third surface US2b as an upper surface.

The upper surface of the upper protrusion 234, the upper surfaces US1a, US2a of the pair of second external electrodes 222, and the upper surfaces US1b, US2b of the pair of third external electrodes 224 may be positioned on the same plane. For example, the upper protrusion 234 may protrude upward from an upper surface 210b of the body portion 210 such that the second protrusion surface PS2 of the upper protrusion 234, the first-second surface US1a of the first-second external electrode 222a, the second-second surface US2a of the second-second external electrode 222b, the first-third surface US1b of the first-third external electrode 224a, and the second-third surface US2b of the second-third external electrode 224b are positioned on the same plane.

As mentioned above, the quadruple electrode capacitor 201 may have the upper protrusion 234.

The upper protrusion 234 may protrude upward from the uppermost insulating layer UIL2 of the body portion 210 such that the upper surface (e.g., second protrusion surface PS2) of the upper protrusion, the upper surfaces (e.g., first-second and second-second surfaces US1a, US2a) of the pair of second external electrodes 222, and the upper surfaces (e.g., first-third and second-third surfaces US1b, US2b) of the pair of third external electrodes 224 are located on the same plane.

Accordingly, in a pick-up process using an adsorption nozzle, the upper surface of the upper protrusion 234, the upper surfaces of the pair of second external electrodes 222, and the upper surfaces of the pair of third external electrodes 224 may provide a flat suction area to which the adsorption nozzle is attached. Thus, the quadruple electrode capacitor 201 may provide a relatively wide suction area US1a, US2a, US1b, US2b, PS2, thereby increasing the stability of the pick-up process.

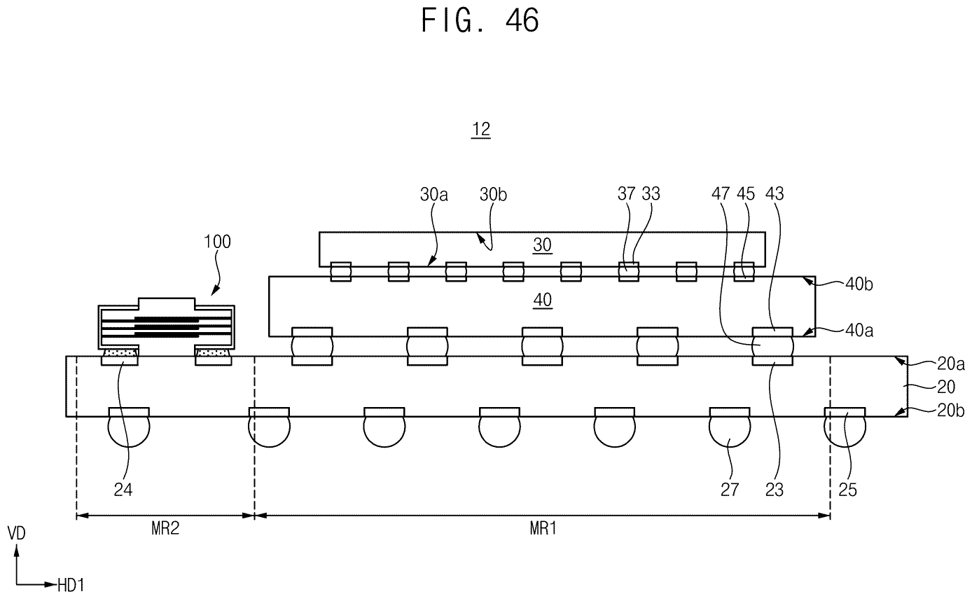

FIG. 46 is a cross-sectional view illustrating a semiconductor package in accordance with an example embodiment.

The semiconductor package illustrated in FIG. 46 is the same as or substantially similar to the semiconductor package described with reference to FIGS. 1 to 4 except for an interposer 40, and thus the same components are indicated by the same reference numerals, and repeated descriptions of the same components are omitted.

Referring to FIG. 46, a semiconductor package 12 may include a substrate structure 20 having a first mounting region MR1 and a second mounting region MR2, at least one semiconductor chip 30 mounted on the first mounting region MR1 of the substrate structure 20, and a double electrode capacitor 100 mounted on the second mounting region MR2 of the substrate structure 20. In addition, the semiconductor package 12 may further include an interposer 40 interposed between the substrate structure 20 and the at least one semiconductor chip 30.

Although the semiconductor package 12 is illustrated as including the double electrode capacitor 100 illustrated in FIGS. 1 to 4, it will be appreciated that example embodiments are not limited thereto. Accordingly, the semiconductor package 12 may include the double electrode capacitor 101 as illustrated in FIGS. 24 and 25 or the double electrode capacitor 102 as illustrated in FIGS. 26 and 27. In addition, the semiconductor package 12 may include the quadruple electrode capacitor 200 as illustrated in FIGS. 30 to 36 or the quadruple electrode capacitor 201 as illustrated in FIGS. 45 and 46.

In some example embodiments, the interposer 40 may include a first surface 40a and a second surface 40b opposite to the first surface 40a. The interposer 40 may include a plurality of first interposer pads 43 provided on the first surface 40a, a plurality of second interposer pads 45 provided on the second surface 40b, and a plurality of second conductive connecting members 47 provided between the plurality of first interposer pads 43 and a plurality of first substrate pads 23. For example, the substrate structure may be a package substrate for connecting a semiconductor device and a printed circuit board (PCB), and the interposer may be a connecting structure for electrically connecting the substrate structure (e.g., the package substrate) and the at least one semiconductor chip.

The interposer 40 may be mounted on the first mounting region MR1 of the substrate structure 20 via the plurality of second conductive connecting members 47 that are provided between the plurality of first interposer pads 43 and the plurality of first substrate pads 23. In addition, at least one semiconductor chip 30 may be mounted on the second surface 40b of the interposer 40 via the plurality of first conductive connecting members 37 that are provided between the plurality of second interposer pads 45 and a plurality of chip pads 33.

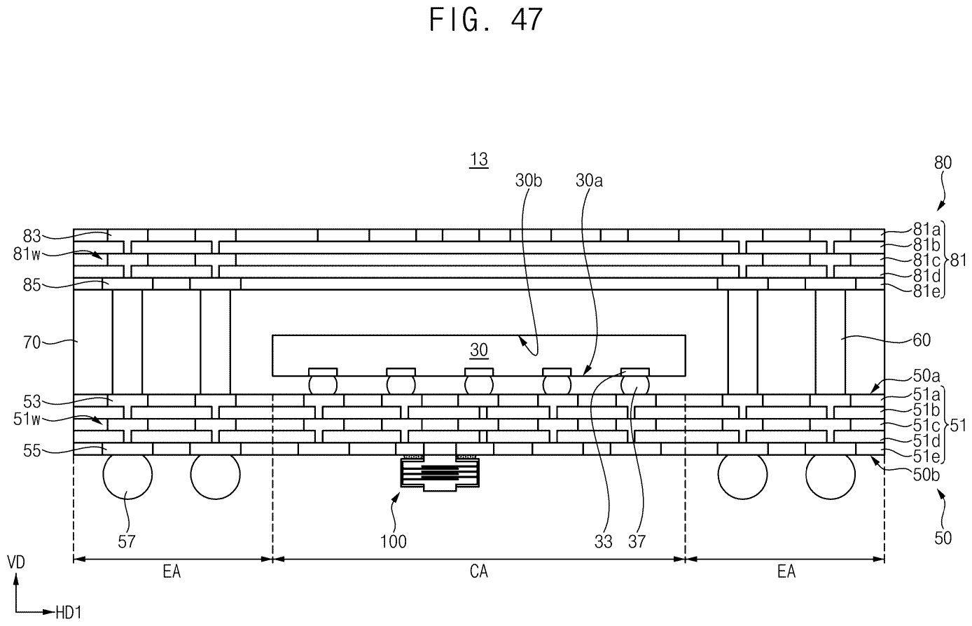

FIG. 47 is a cross-sectional view illustrating a semiconductor package in accordance with an example embodiment.

At least one semiconductor chip 30 and a double electrode capacitor 100 illustrated in FIG. 47 are the same as or substantially similar to the at least one semiconductor chip 30 and the double electrode capacitor 100 of the semiconductor package described with reference to FIGS. 1 to 4, and thus, a repeated description of the at least one semiconductor chip 30 and the double electrode capacitor 100 is omitted.

In addition, although the semiconductor package 13 is illustrated as including the double electrode capacitor 100 illustrated in FIGS. 1 to 4, it will be understood that example embodiments are not limited thereto. Accordingly, the semiconductor package 13 may include the double electrode capacitor 101 illustrated in FIGS. 24 and 25, or the double electrode capacitor 102 illustrated in FIGS. 26 and 27. Additionally, the semiconductor package 13 may include the quadruple electrode capacitor 200 as illustrated in FIGS. 30 to 36 or the quadruple electrode capacitor 201 as illustrated in FIGS. 45 and 46.

Referring to FIG. 47, the semiconductor package 13 may include a first redistribution wiring layer 50 having a first surface 50a having a central region CA and a peripheral region EA surrounding the central region CA and a second surface 50b opposite to the first surface 50a, at least one semiconductor chip 30 mounted on the central region CA of the first redistribution wiring layer 50, conductive pillars 60 provided on the peripheral region EA of the first redistribution wiring layer 50, a molding member 70 provided on the first surface 50a of the first redistribution wiring layer 50, and a second redistribution wiring layer 80 provided on the molding member 70. In addition, the semiconductor package 13 may include a double electrode capacitor 100 provided on the second surface 50b of the first redistribution wiring layer 50.

In some example embodiments, the first redistribution wiring layer 50 may include a plurality of first insulating layers 51a, 51b, 51c, 51d, 51e and a plurality of first internal wirings 51w provided in the plurality of first insulating layers 51a, 51b, 51c, 51d, 51e. In addition, the first redistribution wiring layer 50 may include a plurality of first upper pads 53 that are at least partially exposed from an uppermost insulating layer 51a among the plurality of first insulating layers 51a, 51b, 51c, 51d, 51e and electrically connected to the plurality of first internal wirings 51w. The first redistribution wiring layer 50 may include a plurality of first lower pads 55 that are at least partially exposed from the lowermost insulating layer 51e among the plurality of first insulating layers 51a, 51b, 51c, 51d, 51e and electrically connected to the plurality of first internal wirings 51w. In addition, the first redistribution wiring layer 50 may further include a plurality of second external connecting members 57 that are respectively provided on the plurality of first lower pads 55.

For example, the plurality of first internal wirings 51w, the plurality of first upper pads 53, the plurality of first lower pads 55, and the plurality of second external connecting members 57 may include a conductive metal material for electrical connection. For example, the plurality of second external connecting members may be structures for connecting an external device such as printed circuit board (PCB) to a semiconductor package.

At least one semiconductor chip 30 may be mounted on the central region CA of the first redistribution wiring layer 50 via a plurality of first conductive connecting members 37 that are provided between the plurality of first upper pads 53 and a plurality of chip pads 33.

In some example embodiments, the conductive pillars 60 may be provided on some upper pads, respectively, among the plurality of first upper pads 53 provided in the peripheral region EA. For example, the conductive pillars 60 may be structures for electrically connecting the first redistribution wiring layer 50 and the second redistribution wiring layer 80. The conductive pillars may include a conductive metal material.

In some example embodiments, the molding member 70 may be provided on the first surface 50a of the first redistribution wiring layer 50 to cover the at least one semiconductor chip 30 and the conductive pillars 60 and to at least partially expose the conductive pillars (e.g., to expose top surfaces of the conductive pillars). For example, the molding member may include an epoxy molding compound EMC.

In some example embodiments, the second redistribution wiring layer 80 may include a plurality of second insulating layers 81a, 81b, 81c, 81d, 81e and a plurality of second internal wirings 81w provided in the plurality of second insulating layers 81a, 81b, 81c, 81d, 81e. In addition, the second redistribution wiring layer 80 may include a plurality of second upper pads 83 that are at least partially exposed from an uppermost insulating layer 81a among the plurality of second insulating layers 81a, 81b, 81c, 81d, 81e and electrically connected to the plurality of second internal wirings 81w. The second redistribution wiring layer 80 may include a plurality of second lower pads 85 that are at least partially exposed from a lowermost insulating layer 81e among the plurality of second insulating layers 81a, 81b, 81c, 81d, 81e and electrically connected to the plurality of second internal wirings 81w. For example, the plurality of second internal wirings 81w, the plurality of second upper pads 83, and the plurality of second lower pads 85 may include a conductive metal material for electrical connection.

The second redistribution wiring layer 80 may be arranged within the peripheral region EA and may be electrically connected to the first redistribution wiring layer 50 via the conductive pillars 60 that are provided between the plurality of first upper pads 53 and the plurality of second lower pads 85.

The semiconductor package may include semiconductor devices such as logic devices or memory devices. The semiconductor package may include logic devices such as central processing units (CPUs), main processing units (MPUs), or application processors (APs), or the like, volatile memory devices such as DRAM devices, HBM devices, or non-volatile memory devices such as flash memory devices, PRAM devices, MRAM devices, ReRAM devices, or the like.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present inventive concepts. Accordingly, all such modifications are intended to be included within the scope of example embodiments as defined in the claims.

What is claimed is:

1. A semiconductor package, comprising:
a substrate structure having a first mounting region and a second mounting region;
at least one semiconductor chip on the first mounting region of the substrate structure; and
a double electrode capacitor on the second mounting region of the substrate structure,
wherein the double electrode capacitor comprises
a pair of first external electrodes electrically connected to the substrate structure,
a body portion including
a plurality of insulating layers between the pair of first external electrodes, and
a plurality of internal electrodes between the plurality of insulating layers and extending in a horizontal direction to at least partially contact a portion of the pair of first external electrodes, and
a lower bump structure protruding vertically downward from a lowermost insulating layer among the plurality of insulating layers of the body portion, and
wherein the lower bump structure is in contact with the substrate structure.

2. The semiconductor package of claim 1, wherein the substrate structure includes a plurality of first substrate pads on the first mounting region and a plurality of second substrate pads on the second mounting region.

3. The semiconductor package of claim 2, further comprising:
a solder layer between each of the plurality of second substrate pads of the substrate structure and a corresponding one of the pair of first external electrodes of the double electrode capacitor to electrically connect the substrate structure and the double electrode capacitor.

4. The semiconductor package of claim 3, wherein the solder layer has a first contact surface in contact with a corresponding one of the plurality of second substrate pads, and the lower bump structure has a second contact surface in contact with the substrate structure.

5. The semiconductor package of claim 4, wherein a vertical distance from a lower surface of the lowermost insulating layer to the first contact surface has a first distance, and a vertical distance from a lower surface of the lowermost insulating layer to the second contact surface has a second distance that is same as the first distance.

6. The semiconductor package of claim 1, further comprising:
an interposer between the substrate structure and the at least one semiconductor chip.

7. The semiconductor package of claim 1, wherein the double electrode capacitor comprises an upper protrusion that protrudes vertically upward from an uppermost insulating layer among the plurality of insulating layers of the body portion.

8. The semiconductor package of claim 7, wherein an upper surface of the upper protrusion and upper surfaces of the pair of first external electrodes are on a same plane.

9. The semiconductor package of claim 7, wherein a distance by which the lower bump structure protrudes vertically from a lower surface of the lowermost insulating layer has a first distance, and a distance by which the upper protrusion protrudes from an upper surface of the uppermost insulating layer has a third distance that is same as the first distance.

10. The semiconductor package of claim 9, wherein
the double electrode capacitor includes a first side protrusion that protrudes horizontally from a first side portion of the body portion and a second side protrusion that protrudes horizontally from a second side portion of the body portion,
a distance by which the first side protrusion protrudes from the first side portion has a fourth distance that is same as the first distance, and
a distance by which the second side protrusion protrudes from the second side portion has a fifth distance that is same as the first distance.

11. A semiconductor package, comprising:
a substrate structure having a first mounting region and a second mounting region;
at least one semiconductor chip on the first mounting region of the substrate structure; and
a quadruple electrode capacitor on the second mounting region of the substrate structure and electrically connected to the substrate structure,
wherein the quadruple electrode capacitor comprises
a pair of first external electrodes spaced apart from each other in a horizontal direction,
a pair of second external electrodes spaced apart from the pair of first external electrodes in the horizontal direction,
a body portion including
a plurality of insulating layers between the pair of first external electrodes and the pair of second external electrodes, and
a plurality of internal electrodes between the plurality of insulating layers and extending in the horizontal direction to at least partially contact at least a portion of the pair of first external electrodes and the pair of second external electrodes, and
a lower bump structure protruding downward in a vertical direction from a lowermost insulating layer among the plurality of insulating layers of the body portion, and
wherein the lower bump structure is in contact with the substrate structure.

12. The semiconductor package of claim 11, wherein the substrate structure includes a plurality of first substrate pads on the first mounting region and a plurality of second substrate pads on the second mounting region.

13. The semiconductor package of claim 12, further comprising:
a solder layer between each of the plurality of second substrate pads and a corresponding one of the pair of first external electrodes and the pair of second external electrodes, the solder layer electrically connecting the substrate structure and the quadruple electrode capacitor.

14. The semiconductor package of claim 13, wherein the solder layer has a first contact surface in contact with the second substrate pad, and the lower bump structure has a second contact surface in contact with the substrate structure.

15. The semiconductor package of claim 14, wherein a vertical distance from a lower surface of the lowermost insulating layer to the first contact surface has a second distance, and a vertical distance from a lower surface of the lowermost insulating layer to the second contact surface has a first distance that is same as the second distance.

16. The semiconductor package of claim 11, further comprising:
an interposer between the substrate structure and the at least one semiconductor chip.

17. The semiconductor package of claim 11, wherein the quadruple electrode capacitor comprises an upper protrusion that protrudes vertically upward from an uppermost insulating layer among the plurality of insulating layers of the body portion.

18. The semiconductor package of claim 17, wherein an upper surface of the upper protrusion, upper surfaces of the pair of first external electrodes, and upper surfaces of the pair of second external electrodes are on a same plane.

19. The semiconductor package of claim 17, wherein the lower bump structure protrudes vertically from a lower surface of the lowermost insulating layer by a first distance, and the upper protrusion protrudes from an upper surface of the uppermost insulating layer by a third distance that is same as the first distance.

20. A semiconductor package, comprising:
a first redistribution wiring layer having a first surface and a second surface opposite to the first surface, the first surface having a central region and a peripheral region surrounding the central region;
at least one semiconductor chip on the central region of the first redistribution wiring layer;
conductive pillars on the peripheral region of the first redistribution wiring layer;
a molding member on the first surface of the first redistribution wiring layer, the molding member covering the at least one semiconductor chip and the conductive pillars and exposing a top surface of the conductive pillars;
a second redistribution wiring layer on the molding member and electrically connected to the first redistribution wiring layer via the conductive pillars; and
a double electrode capacitor on the second surface of the first redistribution wiring layer,
wherein the double electrode capacitor includes
a pair of first external electrodes electrically connected to the first redistribution wiring layer,
a body portion including a plurality of insulating layers and a plurality of internal electrodes, the plurality of insulating layers being between the pair of first external electrodes, the plurality of internal electrodes being between the plurality of insulating layers and extending in a horizontal direction so as to at least partially contact a portion of the pair of first external electrodes, and
a lower bump structure extending vertically from an uppermost insulating layer among the plurality of insulating layers of the body portion so as to come into contact with the first redistribution wiring layer.
